(19) United States
(12) Patent Application Publication
(10) Pub. No.: US 2015/0029638 A1
(43) Pub. Date: Jan. 29, 2015

(54) POLYIMIDES AS DIELECTRICS

(71) Applicant: BASF SE, Ludwigshafen (DE)

(72) Inventors: Hans Juerg Kirner, Basel (CH); Stephanie Leuenberger, Metzerlen (CH); Emmanuel Martin, Folgensbourg (FR)

(73) Assignee: BASF SE, Ludwigshafen (DE)

(21) Appl. No.: 14/384,208

(22) PCT Filed: Mar. 27, 2013
(86) PCT No.: PCT/IB13/52426

§ 371 Date: Sep. 10, 2014

Related U.S. Application Data
(60) Provisional application No. 61/616,432, filed on Mar. 28, 2012.

(30) Foreign Application Priority Data
Mar. 28, 2012 (EP) 12161694.0

(51) Int. Cl. H01B 3/30; H01L 23/58; H01B 19/02; H01G 4/14; H01B 19/04; H01G 4/18; H01L 21/02

(52) U.S. Cl. CPC H01B 3/306; H01G 4/18; H01L 23/58; H01L 21/02118; H01L 21/02354; H01G 4/14; H01B 19/04; H01B 19/02
USPC 361/311; 528/423; 257/632; 438/780; 427/79; 427/553

(57) ABSTRACT

Polyimides derived from a primary aromatic diamine and aromatic dianhydride mono-mer moieties, wherein one or more of said moieties contain at least one substituent on the aromatic ring selected from propyl and butyl, especially from isopropyl, isobutyl, tert.butyl, show good solubility and are well suitable as dielectric material in electronic devices such as capacitors and organic field effect transistors.

The present invention relates to a process for the preparation of an organic electronic device, such as a capacitor or transistor on a substrate, to the device obtainable by that process, to certain novel polyimides, and their use as dielectrics, especially as dielectric layer in printed electronic devices such as capacitors and organic field-effect transistors (OFETs).

Transistors, and in particular OFETs, are used e.g. as components for printed electronic devices such as organic light emitting display, e-paper, liquid crystal display and radiofrequency identification tags.

An organic field effect transistor (OFET) comprises a semiconducting layer comprising an organic semiconducting material, a dielectric layer comprising a dielectric material, a gate electrode and source/drain electrodes.

Especially desirable are OFETs wherein the dielectric material can be applied by solution processing techniques. Solution processing techniques are convenient from the point of processability, and can also be applied to plastic substrates. Thus, organic dielectric materials, which are compatible with solution processing techniques, allow the production of low cost organic field effect transistors on flexible substrates.

Kato, Y.; Iba, S.; Teramoto, R.; Sekitani, T.; Someya, T., Appl. Phys. Lett. 2004, 84(19), 3789 to 3791 describes a Bottom-Gate Bottom-Contact organic field-effect transistors comprising a pentacene top layer (semiconducting layer), a polyimide layer (dielectric gate layer) and a polyethylenenapthalate (PEN) base film (substrate). The transistor is prepared using a process which comprises the following steps:

(i) evaporating gate electrodes consisting of gold and chromium layers through a shadow mask on 125 μm thick PEN film in a vacuum system, (ii) spin-coating a polyimide precursor on the PEN base film and evaporating the solvent at 90° C., (iii) curing the polyimide precursor at 180° C. to obtain a polyimide gate dielectric layer, (iv) subliming pentacene through a shadow mask at ambient temperature on the polyimide gate dielectric layer, and (v) evaporating source-drain electrodes consisting of gold layers through a shadow mask. A transistor with a 990 nm polyimide gate dielectric layer shows a channel length (L) of 100 μm, a width (W) of 1.9 mm, an on/off ratio of 10⁶ (if the source drain current (I_{DS}) at gate voltage (V_{GS}) is 35 V) and a mobility of 0.3 cm²/Vs. The leakage current density of capacitors comprising a 540 nm thick polyimide layer between two gold electrodes is less than 0.1 nA/cm² at 40 V and less than 1.1 nA/cm² at 100 V.

Lee, J. H.; Kim, J. Y.; Yi, M. H.; Ka, J. W.; Hwang, T. S.; Ahn, T. Mol. Cryst. Liq. Cryst. 2005, 519, 192-198 describes a Bottom-Gate Bottom-Contact organic field-effect transistor comprising a pentacene top layer (semiconducting layer), a cross-linked polyimide layer (dielectric gate layer) and glass (substrate). The transistor is prepared using a process which comprises the following steps: (i) patterning indium tin oxide of indium tin oxide coated glass as 2 mm wide stripes to obtain glass with indium tin oxide gate electrodes, (ii) spin-coating a solution of hydroxyl group containing polyimide (prepared by reacting 2,2-bis-(3,4-dicarboxyphenyl)hexafluoropropane dianhydride and 3,3′-dihydroxy-4,4′-diaminobiphenyl), trimethylolpropane triglycidyl ether, benzoyl peroxide and triphenylsulfonium triflate as photoacid in γ-butyrolactone on the glass with the indium tin oxide gate electrodes and evaporating the solvent at 100° C., (iii) crosslinking the hydroxyl group containing polyimide and trimethylolpropane triglycidyl ether by exposure to UV light followed by hardening at 160° C. for 30 minutes to obtain a 300 nm thick polyimide gate dielectric layer, (iv) depositing on top of the gate dielectric layer a 60 nm thick pentacene layer through a shadow mask using thermal evaporation at a pressure of 1×10⁻⁶ torr, and (v) evaporating source-drain gold electrodes on top of the pentacene layer. The transistor so produced shows a channel length (L) of 50 μm, a width (W) of 1.0 mm, an on/off ratio of 1.55×10⁵ and a mobility of 0.203 cm²/Vs. The leakage current density of capacitors consisting of a 300 nm thick cross-linked polyimide layer between two gold electrodes is less than 2.33×10⁻¹⁰ A/cm² at 3.3 MV/cm indicating that the dielectric layer is resistant to moisture and other environmental conditions.

Pyo, S.; Lee, M.; Jeon, J.; Lee, J. H.; Yi, M. H.; Kim, J. S. Adv. Funct. Mater. 2005, 15(4), 619 to 626 describes a Bottom-gate Bottom-contact organic field-effect transistor comprising a pentacene top layer (semiconducting layer), a patterned polyimide layer (prepared from 3,3′,4,4′-benzophenone tetracarboxylic dianhydride (BTDA) and 7-(3,5-diaminobenzoyloxy)coumarine) (dielectric gate layer) and glass (substrate). The transistor is prepared using a process which comprises the following steps: (i) depositing gold electrodes through a shadow mask by thermal evaporation on the glass substrate (ii) spin-coating the precursor of the polyimide (namely the poly(amic acid)) on top of the gate electrode and baking at 90° C. for 2 minutes, (iii) crosslinking parts of the poly(amic acid) film by irradiating with UV light at 280 to 310 nm through a mask followed by post-exposure baking at 160° C. for 19 minutes, (iv) removing the not cross-linked parts of the poly(amic acid) film by dipping into aqueous tetramethylammonium hydroxide solution followed by rinsing with water, (v) thermally converting the patterned crosslinked poly(amic acid) film obtained in step (iv) to a patterned polyimide layer (300 nm thick) by baking at 250° C. for 1 minute, (vi) depositing a 60 nm thick pentacene layer on top of the polyimide film through a shadow mask by thermal evaporation, and (vii) thermally evaporating gold source and drain electrodes on top of the pentacene layer through a shadow mask. The leakage current density of capacitors consisting of a polyimide layer between two gold electrodes is less than 1.4×10⁻⁷ A/cm². The breakdown voltage of this gate insulator was more than 2 MV cm⁻¹. The capacitance of the film was found to be 129 pF/mm². The patterned polyamide layer allows the creation of access to the gate electrode.

KR-A-2008-0074417 describes a low temperature soluble mixture consisting of two polyimides, which mixture is suitable as insulating layer in transistors. In both polyimides the group R (which is the group carrying the four carboxylic acid functionalities forming the two imide groups) is at least one tetravalent group including a specific aliphatic cyclic tetravalent group. In the second polyimide the group R² (which is the group carrying the two amine functionalities forming the two imide groups) is at least a divalent group including a divalent aromatic group having a pendant alkyl group. Exemplified is, for example, a mixture consisting of polyimide SPI-3 (prepared from 1-(3,5-diaminophenyl)-3-octadecyl-succinic imide and 5-(2,5-dioxotetrahydrfuryl)3-methylcyclohexane-1,2-dicarboxylic dianhydride) and polyimide SPI-1 (prepared from 4,4′-diamino diphenylmethane (or methylenedianiline) and 5-(2,5-dioxotetrahydrfuryl)3-methylcaclohexane-1,2-dicarboxylic dianhydride) in γ-butyrolactone and cyclohexanone. A transistor is prepared using a process which comprises the following steps: (i) deposing a gate electrode through a mask, (ii) spin-coating a polyimide mixture and drying at 90° C., (ii) baking at 150° C., (iii) depositing pentacene by vacuum evaporation, (iv) depositing source-drain electrodes. As substrate glass and polyethersulfone is used.

Sim, K.; Choi, Y.; Kim, H.; Cho, S.; Yoon, S. C.; Pyo, S. Organic Electronics 2009, 10, 506-510 describes a bottom gate organic field-effect transistor comprising a 6,13-bis(triisopropyl-silylethynyl)pentacene (TIPS pentacene) top layer (semiconducting layer), a low-temperature processable polyimide layer (prepared from 3,3′,4,4′-benzophenone-tetracarboxylic dianhydride (BTDA) and 4,4′-diamino-3,3′-dimethyl-diphenylmethane (DADM)) (dielectric gate layer) and glass (substrate). A transistor is prepared using a process which comprises the following steps: (i) photo-lithographically patterning indium tin oxide on a glass substrate, (ii) spin-coating a solution of BPDA-DADM polyimide in N-methylpyrrolidone (NMP) on top of the gate electrode, (iii) soft baking at 90° C. for 1 minute, (iv) further baking at 175° C. for 1 hour in vacuum, and (v) drop coating a solution of TIPS pentacene and a polymeric binder in o-dichloromethane on the BPDA-DADM polyimide layer, (vi) baking at 90° C. for 1 hour in vacuum, (vii) thermally evaporating 60 nm thick source and drain gold electrodes through a shadow mask. The transistor so produced shows a channel length (L) of 50 μm, a width (W) of 3 mm, an on/off ratio of 1.46×10⁶ and a mobility of 0.15 cm²/Vs.

Chou, W.-Y.; Kuo, C.-W.; Chang, C.-W.; Yeh, B.-L.; Chang, M.-H. J. Mater. Chem. 2010, 20, 5474 to 5480 describes a bottom gate organic field-effect transistor comprising a pentacene top layer (semiconducting layer), a photosensitive polyimide (prepared from 4,4′-oxydianiline (ODA), 4,4′-(1,3-phenylenedioxy)dianiline (TPE-Q), 4-(10,13-dimethyl-17-(6-methylheptan-2-yl)-2,3,4,7,8,9,10,11,12,13,14,15,16,17-tetradecahydro-1H-cyclopenta[a]phenanthren-3-yloxy)benzene-1,3-diamine (CHDA), pyromellitic dianhydride (PDMA), and cyclobutane-1,2,3,4-tetracarboxylic dianhydride (CBDA)) layer (dielectric gate layer), a silicium dioxide layer (dielectric gate layer) and heavily doped n-type silicium (111) wafer (gate and substrate). The photosensitive polyimide used only absorbs at a wavelength of 250 to 300 nm. The transistor is prepared using a process which comprises the following steps: (i) plasma-enhanced chemical vapour depositing a 300 nm thick silicium dioxide layer, (ii) spin-coating a 80 nm thick photosensitive polyimide layer on the silicium dioxide layer, (iii) baking (removing the solvent of) the photosensitive polyimide layer at 220° C. for 60 minutes, (iv) irradiating with UV light, (v) depositing a 70 nm thick pentacene layer onto the photosensitive polyimide layer at room temperature by vacuum sublimation, and (vi) depositing silver source-drain electrodes on the pentacene film through a shadow mask. The transistor so produced shows a channel length (L) of 120 μm, a width (W) of 1920 μm, an on/off ratio of 10³ to 10⁵ (depending on the UV dose applied) and an average mobility of 6.0 cm²/Vs. The surface energy, surface carriers and capacitance of the polyimide gate dielectric can be tuned by varying irradiation doses of UV light on the photosensitive polyimide surface.

KR-A-2010-0049999 describes two soluble photocurable polyimides suitable for use as insulator in transistors. In both polyimides the group R (which is the group carrying the four carboxylic acid functionalities forming the two imide groups) is at least one tetravalent group including a specific aliphatic cyclic tetravalent group. In both polyimide the group R¹ (which is the group carrying the two amine functionalities forming the two imide groups) carries an optionally substituted photocurable cinnamoyl group. For example, the polyimide KPSPI-1 is prepared from 5-(2,5-dioxotetrahydrfuryl)-3-methylcyclohexane-1,2-dicarboxylic dianhydride and 3,3-dihydroxybenzidine, followed by reaction with cinnamoyl chloride. The polyimide layer can be prepared by (i) spin-coating a 9 weight % solution of the photocurable polyimide (KPSPI-1) in γ-butyrolactone and baking at 90° C. for 10 minutes, (iii) curing by UV irradiation (300 to 400 nm), (iii) hard-baking at 160° C. for 30 minutes. The leakage current density of capacitors consisting of the photocured polyimide layer (KPSPI-1) between two gold electrodes is 7.84×10⁻¹¹ A/cm². The breakdown voltage of KPSPI-1 is 3 MV cm⁻¹.

The disadvantage of above processes for the preparation of organic field effect transistors having a dielectric layer comprising a polyimide is that the formation of the dielectric layer requires temperatures of at least 150° C. These high temperatures are not compliable with all kinds of plastic substrates, for example these temperatures are not compliable with polycarbonate substrates, as polycarbonate has a glass temperature (Tg) of 150° C. and softens gradually above this temperature. However, polycarbonate is an ideal substrate for preparing thin and flexible organic field effect transistors.

It is the object of the present invention to provide a dielectric material which allows easy solution processing while resulting in good dielectric properties, adherence and optionally crosslinking under gentle thermal treatment (preferably below 150°, more preferably below 120° C., e.g. using temperatures from the range 20-140° C., or)30-120° and/or irradiation.

The object of the invention is achieved using a polyimide as a dielectric material, which polyimide (in the following referred to as “polyimide A”) is obtainable by reaction of a primary aromatic diamine with an aromatic dianhydride, where at least a part of the monomer moieties, e.g. 10 mol-% of the diamine and/or the dianhydride, especially of the diamine, is substituted on its aromatic ring by at least one alkyl moiety selected from propyl and butyl. The layer of polyimide A is subsequently cured to obtain the dielectric layer comprising polyimide B as described below in more detail.

The invention thus pertains to an electronic device, generally an organic electronic device, as it may be prepared in a printing process on a substrate. The substrate may be glass, but is typically a plastic film or sheet. Typical devices are capacitors, transistors such as an electronic field effect transistor (OFET), or devices comprising said capacitor and/or transistor. The device of the invention contains at least one dielectric material, usually in the form of a dielectric layer, which comprises a polyimide based on primary aromatic diamine and aromatic dianhydride monomer moieties, wherein one or more of said moieties contain at least one substituent on the aromatic ring selected from propyl and butyl, especially from isopropyl, isobutyl, tert.butyl; most preferred is an aromatic polyimide dielectric containing one or more substituents isopropyl on the aromatic ring. The device of the invention generally contains at least one further layer of a functional material, mainly selected from conductors and semiconductors, which usually stands in direct contact with the present polyimide dielectric material or layer; examples are OFETs containing the layer of dielectric material according to the invention in direct contact with the electrode and/or the semiconductor.

Preferred polyimides are those wherein a fraction of the monomer moieties, e.g. 10 mol-% of the diamine and/or the dianhydride, and especially of the diamine, carries at least one of said propyl and/or butyl substituents on its aromatic ring.

The transistor, especially OFET, of the invention is characterized in that it comprises at least one layer of semiconducting material and at least one dielectric layer, wherein the dielectric layer comprises a polyimide based on primary aromatic diamine and aromatic dianhydride monomer moieties, characterized in that at least a part of the monomer moieties, e.g. 10 mol-% of the diamine and/or the dianhydride and especially of the diamine, is substituted on its aromatic ring by at least one alkyl moiety selected from propyl and butyl, especially from isopropyl, isobutyl, tert.butyl, most especially isopropyl.

Present invention further provides a process of the for the preparation of an electronic device, such as a capacitor or transistor on a substrate, which process comprises the steps of
i) forming a layer comprising polyimide A by applying polyimide A on a layer of a conductor or semiconductor or on the substrate, and
ii) irradiating and/or heating the layer comprising polyimide A to form a cured layer comprising polyimide B,
   characterized in that polyimide A contains moieties derived from a primary aromatic diamine with an aromatic dianhydride, where the diamine and/or dianhydride moieties, especially diamine moieties, are substituted on the aromatic ring by at least one alkyl moiety selected from propyl and butyl.

Preferably, the process does not comprise a step of heat treatment at a temperature of >=150° C., More preferably, the process does not comprise a step of heat treatment at a temperature of >=140° C. Most preferably, the process does not comprise a step of heat treatment at a temperature of >=120° C. Accordingly, the heat treatment in step (ii), if present, usually requires heating the layer to a temperature from the range 30 to 150° C., preferably 40 to 140° C., especially 50 to 120° C.

The curing by irradiation in step (ii) usually is accomplished by irradiation with light from the range of visible (especially blue) to ultraviolet, typically e.g. from the range 440 nm to 220 nm, generally using radiation sources known in the art. Of special industrial interest is a process wherein the layer comprising photocurable polyimide A is irradiated with light of a wavelength from the range 320 to 440 nm in order to form the layer comprising polyimide B. More preferably it is irradiated with light of a wavelength of 365 nm, 405 nm and/or 435 nm. Most preferably it is irradiated with light of a wavelength of 365 nm.

Preferably, the photocurable polyimide A is a photocurable polyimide, which carries (i) at at least one photosensitive group, and (ii) at least one crosslinkable group.

The photosensitive group is a group that generates a radical by irradiation, preferably with light of a wavelength from the range 320 nm to 440 nm, more preferably with light of a wavelength of 365 nm, 405 nm and/or 435 nm, most preferably with light of a wavelength of 365 nm. Typically, the photosensitive group may be a carbonyl group.

The crosslinkable group is a group which is capable of generating a radical by reaction with another radical, such as the radical generated from the photosensitive group by irradiation as noted above. Typically, the crosslinkable group may be an alkyl group, such as methyl, ethyl, propyl, butyl, or a group containing secondary or tertiary CH like the present isopropyl or iso/tert.butyl moiety.

Preferably, the present polyimide A is a polyimide which is obtainable by reacting a mixture of reactants, which mixture of reactants comprise at least one dianhydride A and/or dianhydride B, and at least one diamine A, wherein
(i) the diamine A is a diamine carrying at least one crosslinkable group, the dianhydride A is a dianhydride carrying at least one photosensitive group, and the dianhydride B is a dianhydride carrying no photosensitive group (see further below),
(ii) the dianhydride A is a dianhydride carrying at least one crosslinkable group and the diamine A is preferably carrying at least one photosensitive group,
(iii) the dianhydride A is a dianhydride carrying at least one crosslinkable group and at least one photosensitive group, or
(iv) the diamine A is a diamine carrying at least one crosslinkable group and at least one photosensitive group,
   wherein the photosensitive group and the crosslinkable group are as defined above. Among the above mixtures of reactants, (i) is preferred.

The dianhydride A is an organic aromatic compound carrying two —C(O)—O—C(O)— functionalities.

The diamine A is an organic aromatic compound carrying two NH₂ functionalities.

Polyimide A is formed by condensation reaction and elimination of one molecule H2O for each linkage formed between the dianhydride moieties with the diamine moieties, thus forming a polyimide of the general structure (I):

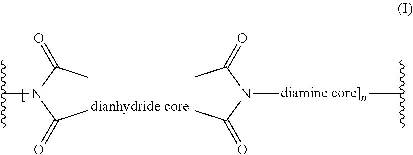

wherein
n ranges from about 10 to 100, especially from 10 to 50.

For example, polyimide A may be obtained according to the scheme

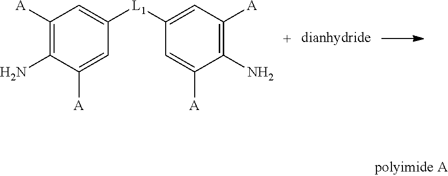

where
L₁ independently is O, S, C₁₋₁₀-alkylene, phenylene or C(O), especially C₁-C₃alkylene such as CH₂;
and
each A independently is selected from hydrogen and C1-C4alkyl, provided that at least 2.5% of the residues A, especially 5 to 95% of the residues A in the polyimide A are propyl or butyl, especially isopropyl or isobutyl or tert.butyl; most especially isopropyl.

End groups of polyimide A may be partly unreacted difunctional monomers (i.e. anhydride or derivatives thereof, or amino), or preferably are residues of primary amines (such as C1-C18 alkylamine, aniline etc.) added during the synthesis for endcapping, see below.

To obtain polyimide A, the mixture of reactants preferably is reacted in a suitable solvent, such as N-methylpyrrolidone, tetrahydrofuran or 1,4-dioxane, at a suitable temperature, for example at a temperature in the range of 10 to 150° C., or at a temperature in the range from 10 to 50° C., or at a temperature in the range from 18 to 30° C.

In a preferred embodiment, the photocurable polyimide A is a polyimide which is obtainable by reacting a mixture of reactants, which mixture of reactants comprise at least one dianhydrides A and at least one diamines A, wherein the dianhydride A is preferably selected from dianhydrides carrying at least one photosensitive group, and the diamines A is a diamine carrying at least one crosslinkable group, wherein the photosensitive group and the crosslinkable group are as defined above.

Preferably, the dianhydride A carrying at least one photosensitive group is a benzophenone derivative carrying two —C(O)—O—O(O)— functionalities. More preferably, the dianhydrides A carrying at least one photosensitive group is a benzophenone derivative carrying two —C(O)—O—O(O)— functionalities, wherein the two —C(O)—O—O(O)— functionalities are directly attached to the same or to different phenyl rings of the benzophenone basic structure.

More preferably, the dianhydride A which is a dianhydride carrying at least one photosensitive group, is selected from the group consisting of

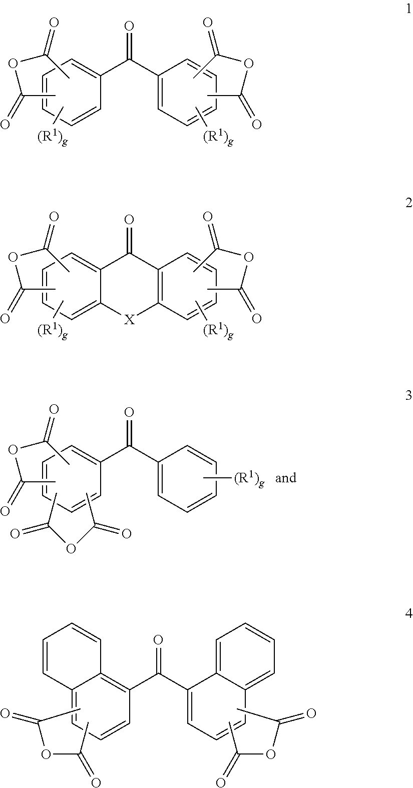

wherein
R¹ is C₁₋₁₀-alkyl, C₁₋₁₀-haloalkyl, halogen or phenyl
g is 0, 1, 2 or 3, preferably 0,
X is a direct bond, CH₂, O, S or C(O), preferably X is a direct bond, CH₂ or O.

Even more preferably, the dianhydride A which is a dianhydride carrying at least one photosensitive group, is selected from the group consisting of

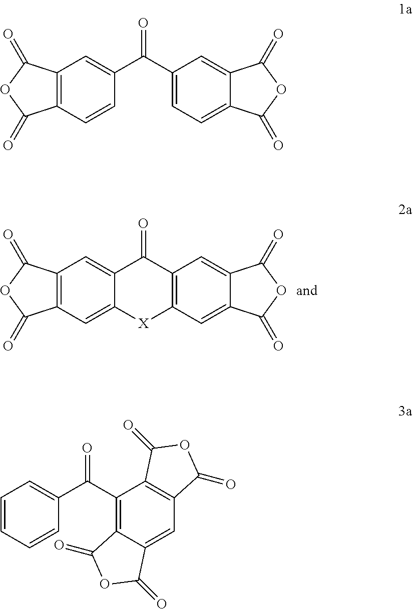

wherein X can be O, S and CH₂.

Examples of the dianhydride of formula (2a) are the dianhydrides of formulae

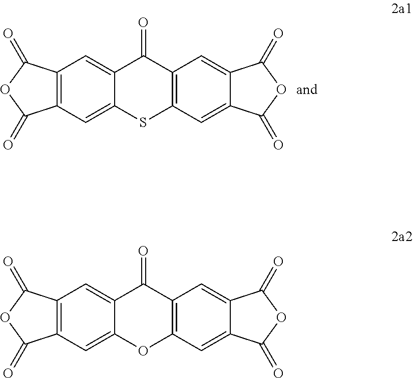 [SMILES: O=c1c2cc3c(=O)oc(=O)c3cc2sc2cc3c(=O)oc(=O)c3cc12 ; O=c1c2cc3c(=O)oc(=O)c3cc2oc2cc3c(=O)oc(=O)c3cc12]

The most preferred dianhydride A, which is a dianhydride carrying at least one photosensitive group, is the dianhydride of formula

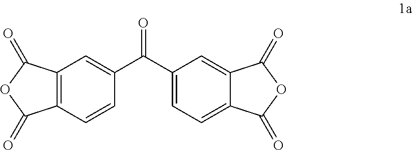 [SMILES: O=C(c1ccc2c(c1)C(=O)OC2=O)c1ccc2c(c1)C(=O)OC2=O]

Dianhydrides of formulae (1), (2), (3) and (4) can either be prepared by methods known in the art or are commercially available. For example, dianhydride (2a1) can be prepared as described in EP 0 181 837, example b, dianhydride (2a2) can be prepared as described in EP 0 181 837 A2, example a. Dianhydride (1a) is commercially available.

Preferably, the diamine A, which is a diamine carrying at least one crosslinkable group, is an organic compound carrying

(i) two amino functionalities,
and
(ii) at least one aromatic ring having attached at least one moiety selected from propyl and butyl, especially from isopropyl and isobutyl; most especially, the aromatic ring in diamine A is substituted by at least one isopropyl group.

Examples of aromatic rings are phenyl and naphthyl. Phenyl is preferred.

More preferably the diamine A, which is a diamine carrying at least one crosslinkable group, is selected from the group consisting of

(i) a diamine of formula

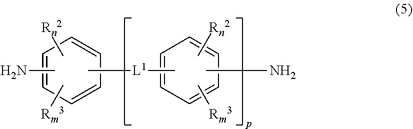

wherein
R², R³ are the same or different and are H, C₁₋₁₀-alkyl or C₄₋₈-cycloalkyl,
n is 1, 2, 3 or 4
m is 0, 1, 2 or 3
provided n+m<=4,
p is 0, 1, 2, 3 or 4,
L¹ is O, S, C₁₋₁₀-alkylene, phenylene or C(O)
wherein C₁₋₁₀-alkylene can be optionally substituted with one or more C₁₋₁₀-alkyl, C₁₋₁₀-haloalkyl and/or C₄₋₈-cycloalkyl, or interrupted by O or S,
(ii) a diamine of formula

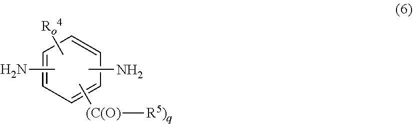

wherein
R⁴ is H, C₁₋₁₀-alkyl or C₄₋₈-cycloalkyl
R⁵ is O—C₁₋₁₀-alkyl, O—C₁₋₁₀-alkylene-O—C₁₋₁₀-alkyl, O—C₁₋₁₀-alkylene-N(C₁₋₁₀-alkyl)₂, N(C₁₋₁₀-alkyl)₂, O-phenyl, W, O—C₁₋₁₀-alkylene-W, O-phenylene-W, N(R⁶)(C₁₋₁₀-alkylene-W) or N(R⁶)(phenylene-W),
wherein
R⁶ is H, C₁₋₁₀-alkyl, C₄₋₁₀-cycloalkyl or C₁₋₁₀-alkylene-W,
W is O—C₂₋₁₀-alkenyl, N(R⁷)(C₂₋₁₀-alkenyl), O—C(O)—CR⁸═CH₂, N(R⁷)(C(O)—CR⁸═CH₂), or

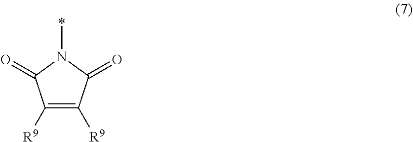

wherein
R⁷ is H, C₁₋₁₀-alkyl, C₄₋₈-cycloalkyl, C₂₋₁₀-alkenyl or C(O)—CR⁸═CH₂,
R⁸ is H, C₁₋₁₀-alkyl or C₄₋₈-cycloalkyl,
R⁹ is H, C₁₋₁₀-alkyl or C₄₋₈-cycloalkyl
q is 1, 2, 3 or 4
o is 0, 1, 2, 3
q+o<=4,
in case o is 0, R⁵ is W, O—C₁₋₁₀-alkylene-W, O-phenylene-W, N(R⁶)(C₁₋₁₀-alkylene-W) or N(R⁶)(phenylene-W),
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S,
and
(iii) a diamine of formula

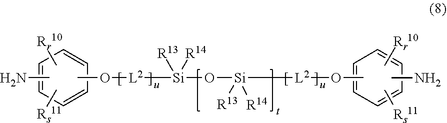

wherein
R¹⁰ and R¹¹ are the same or different and are H, C₁₋₁₀-alkyl or C₄₋₈-cycloalkyl
R¹³ and R¹⁴ are the same and different and are C₁₋₁₀-alkyl, C₁₋₁₀-haloalkyl,
C₄₋₈-cycloalkyl, phenyl, C₂₋₁₀-alkenyl or C₄₋₁₀-cycloalkenyl,
L² is C₁₋₁₀-alkylene or phenylene
r is 0, 1, 2, 3 or 4
s is 0, 1, 2, 3 or 4
r+s<=4
in case both r and s are 0 then at least one of R¹³ and R¹⁴ is C₂₋₁₀-alkenyl or C₄₋₁₀-cycloalkenyl,
t is 0, 1, 2, 3, 4 or 5
u is 0 or 1
wherein C₁₋₁₀-alkylene can be optionally substituted with one or more C₁₋₁₀-alkyl, C₁₋₁₀-haloalkyl and/or C₄₋₈-cycloalkyl, or C₁₋₁₀-alkylene can be optionally interrupted by O or S;
and wherein in at least 10 mol-% of the diamines (i), (ii) and/or (iii), at least one substituent R², R³, R⁴, R¹⁰, R¹¹ is present, which is selected from propyl and butyl, especially from isopropyl and isobutyl and most especially from isopropyl. Preferably, at least 20 mol-% of the diamines, preferably 40 to 100 mol-% of the diamine moieties carry said substituent.

Examples of halogen are fluoro, chloro and bromo.

Examples of C₁₋₁₀-alkyl are methyl, ethyl, propyl, isopropyl, butyl, sec-butyl, isobutyl, tert-butyl, pentyl, 2-ethylbutyl, hexyl, heptyl, octyl, nonyl and decyl. Examples of propyl and butyl are n-propyl, isopropyl, n-butyl, sec-butyl, isobutyl and tert-butyl.

Examples of C₄₋₈-cycloalkyl are cyclobutyl, cyclopentyl, cyclohexyl, cycloheptyl and cyclooctyl.

Examples of C₁₋₁₀-haloalkyl are trifluoromethyl and pentafluoroethyl.

Examples of C₂₋₁₀-alkenyl are vinyl, CH₂—CH═CH₂, CH₂—CH₂—CH═CH₂.

Examples of C₄₋₈-cycloalkenyl are cyclopentyl, cyclohexyl and norbornenyl.

Examples of C₁₋₁₀-alkylene are methylene, ethylene, propylene, butylene, pentylene, hexylene and heptylene. Examples of C₁₋₄-alkylene are methylene, ethylene, propylene and butylene

Examples of C₄₋₈-cycloalkylene are cyclobutylene, cyclopentylene, cyclohexylene and cycloheptylene.

Examples of C₁₋₄-alkanoic acid are acetic acid, propionic acid and butyric acid.

The diamine of formula (5) is preferred to the diamines of formulae (6) and (8).

Preferred diamines of formula (5) are diamines of formula

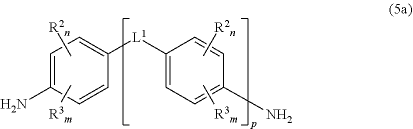

wherein
R², R³ are the same or different and are H, C₁₋₁₀-alkyl or C₄₋₈-cycloalkyl,
n is 1, 2, 3 or 4
m is 0, 1, 2 or 3
provided that n+m<=4, and further provided that at least 10 mol-% of the diamines (5) carry at least one substituent R² and/or R³ which is selected from propyl and butyl, especially from isopropyl and isobutyl and most especially from isopropyl;
p is 0, 1, 2, 3 or 4,
L¹ is O, S, C₁₋₁₀-alkylene, phenylene or C(O)
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Examples of diamines of formula (5a) are

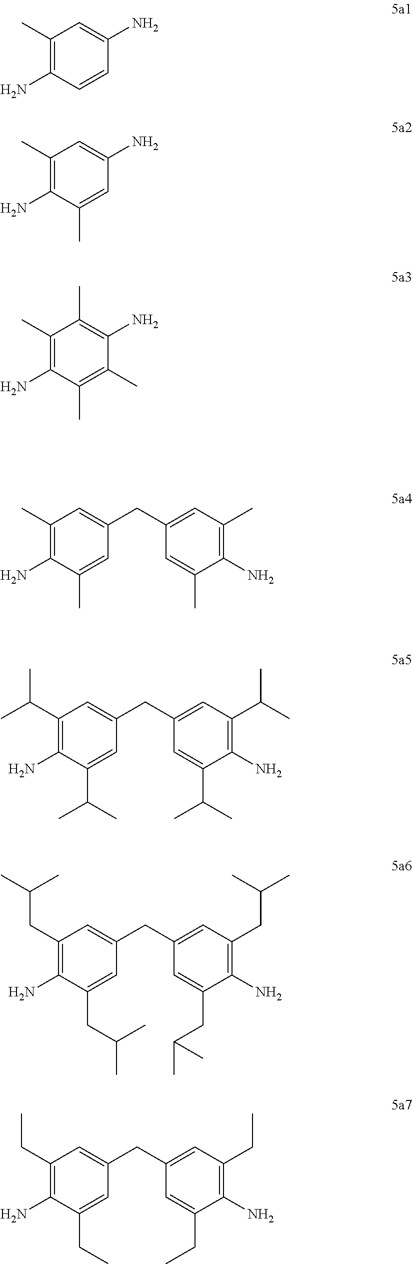

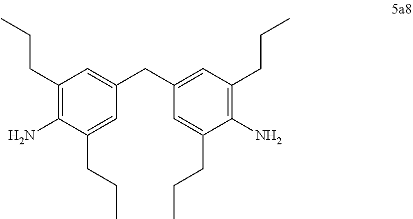 [SMILES: CCCc1cc(Cc2cc(CCC)c(N)c(CCC)c2)cc(CCC)c1N]

In preferred diamines of formula (5a)

R², R³ are the same or different and are H, C₁₋₁₀-alkyl or C₄₋₈-cycloalkyl,
n is 1, 2, 3
m is 0, 1, 2
provided n+m=2, 3 or 4
p is 0, 1, 2, 3 or 4,
L¹ is O, S or C₁₋₁₀-alkylene
wherein C₁₋₁₀-alkylene can be optionally substituted with one or more C₁₋₁₀-alkyl, C₁₋₁₀-haloalkyl and/or C₄₋₈-cycloalkyl.

In more preferred diamines of formula (5a)

R², R³ are the same or different and are C₁₋₁₀-alkyl or C₄₋₈-cycloalkyl,

n is 1, 2,
m is 0, 1,
provided n+m=2
p is 1,
L¹ is O or C₁₋₁₀-alkylene.

In even more preferred diamines of formula (5a)

R² is C₁₋₄-alkyl,
n is 2,
p is 1,
L¹ is O or C₁₋₄-alkylene.

The most preferred diamines of formula (5a) is the diamine of formula

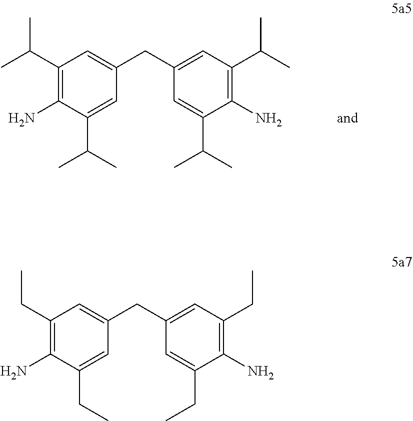 [SMILES: CC(C)c1cc(Cc2cc(C(C)C)c(N)c(C(C)C)c2)cc(C(C)C)c1N ; CCc1cc(Cc2cc(CC)c(N)c(CC)c2)cc(CC)c1N]

The diamines of formula (5) are either commercially available or can be prepared by methods known in the art, for example as described for the diamine of formula (5a4) in Oleinik, I. I.; Oleinik, I. V.; Ivanchev, S. S.; Tolstikov, G. G. Russian J. Org. Chem. 2009, 45, 4, 528 to 535. For example, 4,4′-methylen-bis-(2,6-diisopropylaniline) (5a5) may be obtained in good yield according to the scheme:

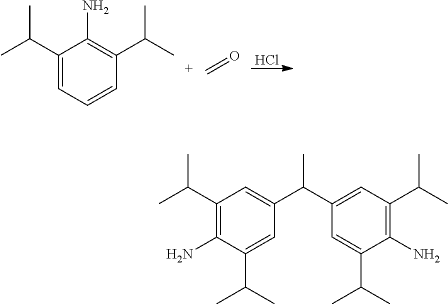

A preferred diamine of formula (6) is a diamine of formula

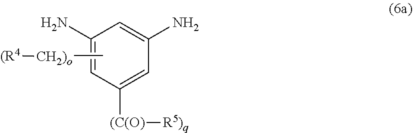

wherein
R⁴ is H, C₁₋₁₀-alkyl or C₄₋₈-cycloalkyl
R⁵ is O—C₁₋₁₀-alkyl, O—C₁₋₁₀-alkylene-O—C₁₋₁₀-alkyl, O—C₁₋₁₀-alkylene-N(C₁₋₁₀-alkyl)₂,
N(C₁₋₁₀-alkyl)₂, O-phenyl, W, O—C₁₋₁₀-alkylene-W, O-phenylene-W, N(R⁶)(C₁₋₁₀-alkylene-W) or N(R⁶)(phenylene-W),
wherein
R⁶ is H, C₁₋₁₀-alkyl, C₄₋₈-cycloalkyl or C₁₋₁₀-alkylene-W,
W is O—C₂₋₁₀-alkenyl, N(R⁷)(C₂₋₁₀-alkenyl), O—C(O)—CR⁸═CH₂, N(R⁷)(C(O)—CR⁸═CH₂), or

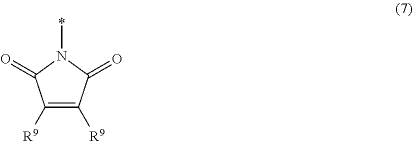

wherein
R⁷ is H, C₁₋₁₀-alkyl, C₄₋₈-cycloalkyl, C₂₋₁₀-alkenyl or C(O)—CR⁸═CH₂,
R⁸ is H, C₁₋₁₀-alkyl or C₄₋₈-cycloalkyl,
R⁹ is H, C₁₋₁₀-alkyl or C₄₋₈-cycloalkyl
q is 1, 2, 3 or 4
o is 0, 1, 2, 3
q+o<=4,
in case o is 0, R⁵ is W, O—C₁₋₁₀-alkylene-W, O-phenylene-W, N(R⁶)(C₁₋₁₀-alkylene-W) or N(R⁶)(phenylene-W),
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

In preferred diamines of formula 6a

o is 0
R⁵ is W, O—C₁₋₁₀-alkylene-W, O-phenylene-W, N(R⁶)(C₁₋₁₀-alkylene-W) or N(R⁶)(phenylene-W),
wherein
R⁶ is H, C₁₋₁₀-alkyl, C₄₋₁₀-cycloalkyl or C₁₋₁₀-alkylene-W,
W is O—C₂₋₁₀-alkenyl, N(R⁷)(C₂₋₁₀-alkenyl), O—C(O)—CR⁸═CH₂, N(R⁷)(C(O)—CR⁸═CH₂), or

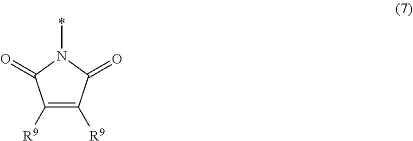

wherein
R⁷ is H, C₁₋₁₀-alkyl, C₄₋₈-cycloalkyl, C₂₋₁₀-alkenyl or C(O)—CR⁸═CH₂,
R⁸ is H, C₁₋₁₀-alkyl or C₄₋₈-cycloalkyl,
R⁹ is H, C₁₋₁₀-alkyl or C₄₋₈-cycloalkyl
q is 1 or 2
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

In more preferred diamines of formula 6a

o is 0
R⁵ is O—C₁₋₁₀-alkylene-W or O-phenylene-W
wherein
W is O—C₂₋₁₀-alkenyl, N(R⁷)(C₂₋₁₀-alkenyl), O—C(O)—CR⁸═CH₂, N(R⁷)(C(O)—CR⁸═CH₂), or

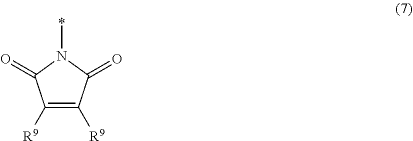

wherein
R⁷ is H, C₁₋₁₀-alkyl, C₄₋₈-cycloalkyl, C₂₋₁₀-alkenyl or C(O)—CR⁸═CH₂,
R⁸ is H, C₁₋₁₀-alkyl or C₄₋₈-cycloalkyl,
R⁹ is C₁₋₁₀-alkyl,
q is 1
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

In most preferred diamines of formula 6a

o is 0
R⁵ is O—C₁₋₁₀-alkylene-W or O-phenylene-W
wherein

### W is

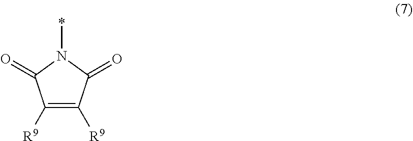

wherein
R⁹ is methyl,
q is 1
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

The most preferred diamine of formula 6a are the diamines of formulae

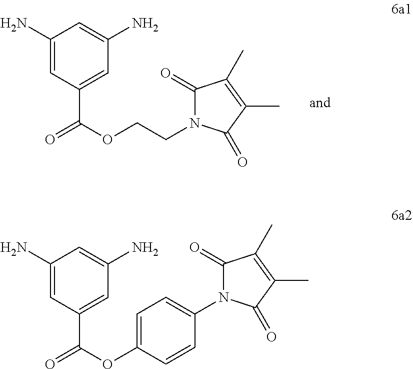 [SMILES: CC1=C(C)C(=O)N(CCOC(=O)c2cc(N)cc(N)c2)C1=O ; CC1=C(C)C(=O)N(c2ccc(OC(=O)c3cc(N)cc(N)c3)cc2)C1=O]

The diamines of formula (6) are either commercially available or can be prepared by methods known in the art. For example, the diamine of formula (6) can be prepared by reacting a dinitrocompound of formula (17) with H—R⁵, followed by reduction of the nitro groups.

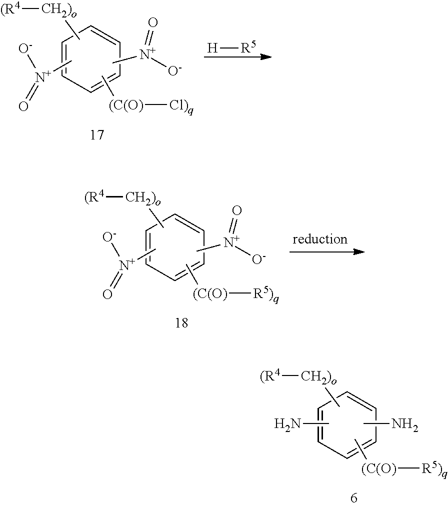

A preferred diamine of formula (8) is the diamine of formula

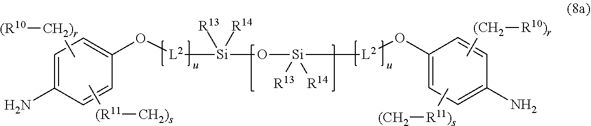

wherein
R¹⁰ and R¹¹ are the same or different and are H, C₁₋₁₀-alkyl or C₄₋₈-cycloalkyl
R¹³ and R¹⁴ are the same and different and are C₁₋₁₀-alkyl, C₁₋₁₀-haloalkyl,
C₄₋₈-cycloalkyl, C₂₋₁₀-alkenyl, C₄₋₁₀-cycloalkenyl or phenyl,
L² is C₁₋₁₀-alkylene or phenylene
r is 0, 1, 2, 3 or 4
s is 0, 1, 2, 3 or 4
r+s<=4
in case both r and s are 0 then at least one of R¹³ and R¹⁴ is C₂₋₁₀-alkenyl or C₄₋₁₀-cycloalkenyl,
t is 0 or an integer from 0 to 50, preferably 0 or an integer from 0 to 25, more preferably 0 or an integer from 1 to 6, most preferably 0 or 1,
u is 0 or 1
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

Preferred diamines of formula (8a) are diamines of formulae

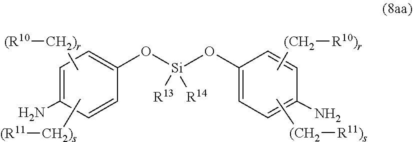

wherein
R¹⁰ and R¹¹ are the same or different and are H, C₁₋₁₀-alkyl or C₄₋₈-cycloalkyl
R¹³ and R¹⁴ are the same and different and are C₁₋₁₀-alkyl, C₄₋₈-cycloalkyl, C₂₋₁₀-alkenyl, C₄₋₁₀-cycloalkenyl or phenyl,
r is 0, 1, 2, 3 or 4
s is 0, 1, 2, 3 or 4
r+s<=4
in case both r and s are 0 then at least one of R¹³ and R¹⁴ is C₂₋₁₀-alkenyl or C₄₋₁₀-cycloalkenyl,
and

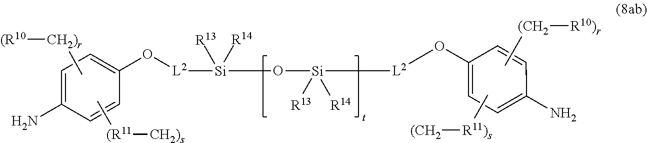

wherein
R¹⁰ and R¹¹ are the same or different and are H, C₁₋₁₀-alkyl or C₄₋₈-cycloalkyl
R¹³ and R¹⁴ are the same and different and are C₁₋₁₀-alkyl, C₄₋₈-cycloalkyl, C₂₋₁₀-alkenyl, C₄₋₁₀-cycloalkenyl or phenyl
L² is C₁₋₁₀-alkylene
r is 0, 1, 2, 3 or 4
s is 0, 1, 2, 3 or 4
r+s<=4
in case both r and s are 0 then at least one of R¹³ and R¹⁴ is C₂₋₁₀-alkenyl or C₄₋₁₀-cycloalkenyl,
t is 0 or an integer from 0 to 50, preferably 0 or an integer from 0 to 25, more preferably 0 or an integer from 1 to 6, most preferably 0 or 1,
wherein C₁₋₁₀-alkylene, can be optionally substituted with one or more C₁₋₁₀-alkyl, C₁₋₁₀-haloalkyl, and/or C₄₋₈-cycloalkyl, or interrupted by O or S.

Examples of diamines of formula (8aa) are

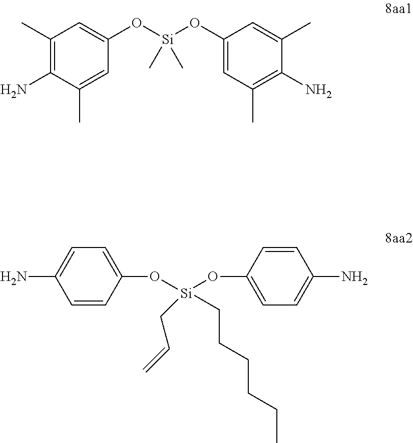 [SMILES: Cc1cc(O[Si](C)(C)Oc2cc(C)c(N)c(C)c2)cc(C)c1N ; C=CC[Si](CCCCCC)(Oc1ccc(N)cc1)Oc1ccc(N)cc1]

An example of a diamine of formula (8ab) is the diamine of formula

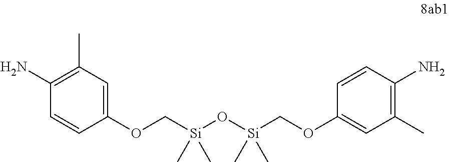 [SMILES: Cc1cc(OC[Si](C)(C)O[Si](C)(C)COc2ccc(N)c(C)c2)ccc1N]

Diamines of formula (8) are either commercially available or can be prepared by methods known in the art, for example diamines of formula (8aa) can be prepared as described by Ismail, R. M. Helv. Chim. Acta 1964, 47, 2405 to 2410, examples 12 to 14, for example diamines of formula (8ab) can be prepared as described in EP 0 054 426 A2, for example in examples XXVI and XXVIII.

The mixture of reactants may further comprise other diamines and/or dianhydrides such as at least one dianhydride B and/or at least one diamine B, wherein the dianhydride B may be any aromatic dianhydride B different from dianhydride A and the diamine B can be any primary diamine B different from diamine A.

The dianhydride B is an organic compound carrying two —C(O)—O—C(O)— functionalities.

The diamine B is an organic compound carrying two NH2 functionalities.

In case the polyimide A is a polyimide which is obtainable by reacting a mixture of reactants, which mixture of reactants comprise at least one dianhydride A and/or dianhydride B, and at least one diamine A, wherein the dianhydride A is carrying at least one photosensitive group, and the diamine A is a diamine carrying at least one crosslinkable group, the dianhydride B is a dianhydride carrying no photosensitive group, and the diamine B is a diamine carrying no crosslinkable group, wherein the photosensitive group and the crosslinkable group are as defined above.

Preferably, dianhydride B, which is a dianhydride carrying no photosensitive group, is an organic compound containing at least one aromatic ring and carrying two —C(O)—O—C(O)— functionalities, wherein the two —C(O)—O—C(O)— functionalities are attached to the same or different aromatic rings.

More preferably, the dianhydride B, which is a dianhydride carrying no photosensitive group, is selected from the group consisting of

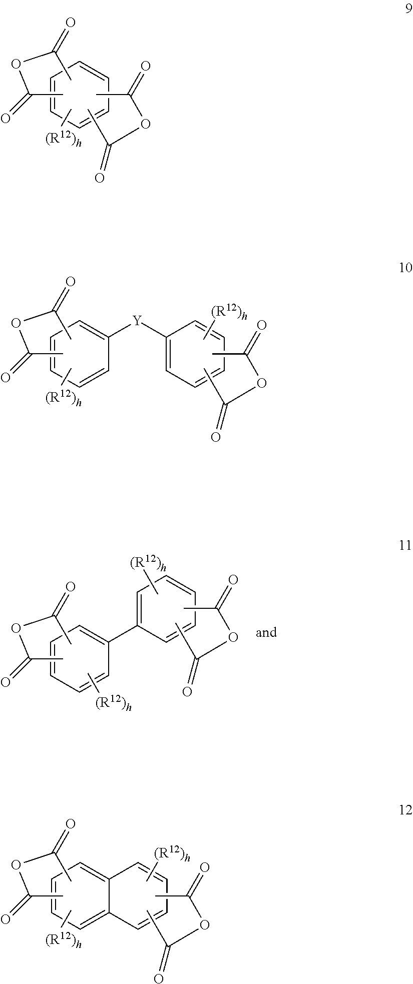

wherein
R¹² is C₁₋₁₀-alkyl, C₁₋₁₀-haloalkyl, halogen or phenyl
h is 0, 1, 2 or 3, preferably 0,
Y is a C₁₋₁₀-alkylene, O or S, preferably Y is CH₂ or O.

Even more preferably, the dianhydride B, which is a dianhydride carrying no photosensitive group, is selected from the group consisting of

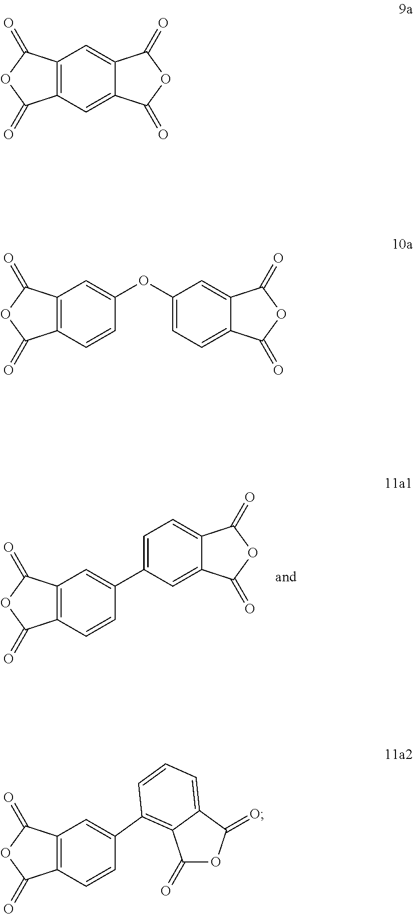 [SMILES: O=c1oc(=O)c2cc3c(=O)oc(=O)c3cc12 ; O=C1OC(=O)c2cc(Oc3ccc4c(c3)C(=O)OC4=O)ccc21 ; O=C1OC(=O)c2cc(-c3ccc4c(c3)C(=O)OC4=O)ccc21 ; O=C1OC(=O)c2cc(-c3cccc4c3C(=O)OC4=O)ccc21]

Most preferably, the dianhydride B, which is a dianhydride carrying no photosensitive group, is

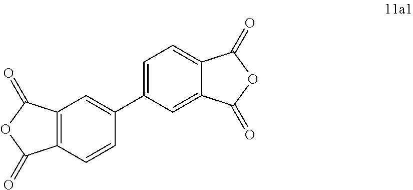 [SMILES: O=C1OC(=O)c2cc(-c3ccc4c(c3)C(=O)OC4=O)ccc21]

The dianhydride B of formulae (9) to (12) are either commercially available or can be prepared by methods known in the art, for example by treatment of the corresponding tetramethyl derivative with HNO₃ at 180° C.

The diamine B, which is a diamine carrying no crosslinkable group, may be selected from the group consisting of

(i) a diamine of formula

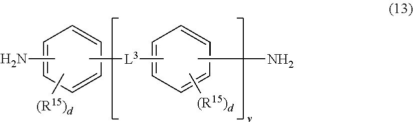

wherein
R¹⁵ is halogen or O—C₁₋₁₀-alkyl,
d is 0, 1, 2, 3 or 4
v is 0, 1, 2, 3 or 4,
L³ is a direct bond, O, S, C₁₋₁₀-alkylene or CO,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S,
(ii) a diamine of formula

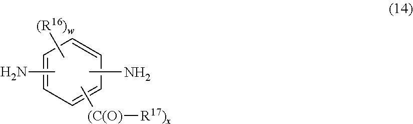

wherein
R¹⁶ is halogen or O-_{C1-10}-alkyl
R¹⁷ is O—C₁₋₁₀-alkyl, O—C₁₋₁₀-alkylene-O—C₁₋₁₀-alkyl, O-phenyl,
O—C₁₋₁₀-alkylene-N(C₁₋₁₀-alkyl)₂ or N(C₁₋₁₀-alkyl)₂
w is 0, 1, 2 or 3
x is 1, 2, 3, 4
w+x<=4,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S,
(iii) a diamine of formula

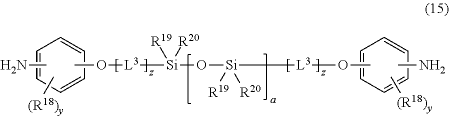

wherein
R¹⁸ is halogen or O—C₁₋₁₀-alkyl,
R¹⁹ and R²⁰ are the same and different and are C₁₋₁₀-alkyl, C₁₋₁₀-haloalkyl or C₄₋₈-cycloalkyl or phenyl,
L³ is C₁₋₁₀-alkylene or phenylene
y is 0, 1, 2, 3 or 4
z is 0 or 1
a is 0 or an integer from 1 to 50, preferably 0 or an integer from 1 to 25,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S,
and
(iv) a diamine of formula

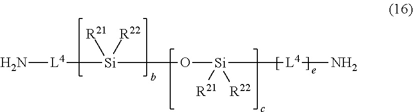

wherein
R²¹ and R²² are the same and different and are C₁₋₁₀-alkyl, C₁₋₁₀-haloalkyl or C₄₋₈-cycloalkyl,
L⁴ is C₁₋₁₀-alkylene, C₄₋₈-cycloalkylene or C₄₋₈-cycloalkylene-Z—C₄₋₈-cycloalkylene,
wherein Z is C₁₋₁₀-alkylene, S, O or CO
b is 0 or 1
c is 0 or an integer from 1 to 50, preferably, 0 or an integer from 1 to 25, more preferably 0 or an integer from 1 to 6, most preferably 0 or 1
e is 0 or 1
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Preferably, diamine B, which is a diamine carrying no crosslinkable group, is a diamine of formula (14) or (16).

A preferred diamine of formula (13) a diamine of formula

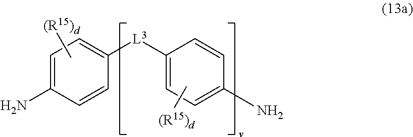

wherein
R¹⁵ is halogen or O—C₁₋₁₀-alkyl,
d is 0, 1, 2, 3 or 4
v is 0, 1, 2, 3 or 4,
L³ is a direct bond, O, S, C₁₋₁₀-alkylene or CO,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Examples of diamines of formula 13a are

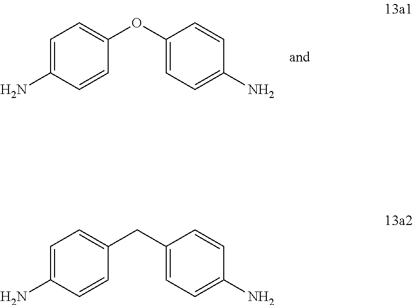 [SMILES: Nc1ccc(Oc2ccc(N)cc2)cc1 ; Nc1ccc(Cc2ccc(N)cc2)cc1]

In preferred diamines of formula (13a)

d is 0, 1 or 2
v is 1
L³ is 0 or C₁₋₁₀-alkylene,
wherein C₁₋₁₀-alkylene can be optionally substituted with one or more C₁₋₁₀-alkyl, C₁₋₁₀-haloalkyl and/or C₄₋₈-cycloalkyl, or interrupted by 0.

In more preferred diamines of formula (13a)

d is 0
v is 1
L³ is 0 or methylene,
wherein methylene can be optionally substituted with one or more C₁₋₁₀-alkyl, C₁₋₁₀-haloalkyl and/or C₄₋₈-cycloalkyl.

The diamines of formula (13) are either commercially available or can be prepared by methods known in the art, for example as described in Ingold, C. K.; Kidd, H. V. J. Chem. Soc. 1933, 984 to 988.

A preferred diamine of formula (14) is the diamine of formula

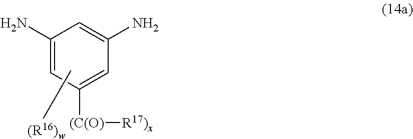

wherein
R¹⁶ is halogen or O-_{C1-10}-alkyl
R¹⁷ is O—C₁₋₁₀-alkyl, O—C₁₋₁₀-alkylene-O—C₁₋₁₀-alkyl, O-phenyl,
O—C₁₋₁₀-alkylene-N(C₁₋₁₀-alkyl)₂ or N(C₁₋₁₀-alkyl)₂
w is 0, 1, 2 or 3
x is 1, 2, 3, 4
w+x<=4,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Examples of diamines of formula (14a) are

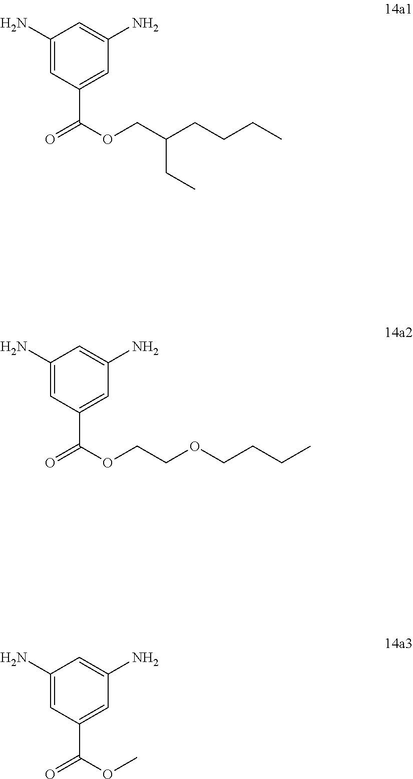 [SMILES: CCCCC(CC)COC(=O)c1cc(N)cc(N)c1 ; CCCCOCCOC(=O)c1cc(N)cc(N)c1 ; COC(=O)c1cc(N)cc(N)c1]

In preferred diamines of formula (14a)

R¹⁶ is halogen or O—C₁₋₁₀-alkyl
R¹⁷ is O—C₁₋₁₀-alkyl, O—C₁₋₁₀-alkylene-O—C₁₋₁₀-alkyl or O-phenyl
w is 0, 1, 2 or 3
x is 1.

In more preferred diamines of formula (14a)

R¹⁶ is halogen or O—C₁₋₁₀-alkyl

R¹⁷ is O—C₁₋₁₀-alkyl
w is 0, 1 or 2
x is 1.

The most preferred diamines of formula (14a) is the diamine of formula

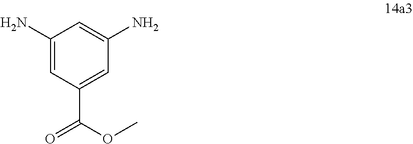

The diamines of formula (14) are either commercially available or can be prepared by methods known in the art.

For example, the diamine of formula (14) can be prepared by reacting a dinitrocompound of formula (19) with H—R¹⁷, followed by reduction of the nitro groups.

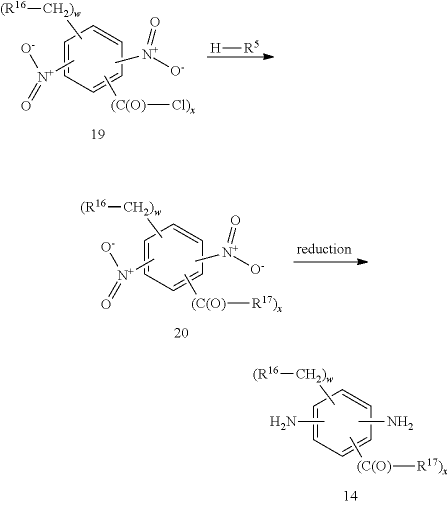

Preferred diamines of formula (15) are diamines of formula

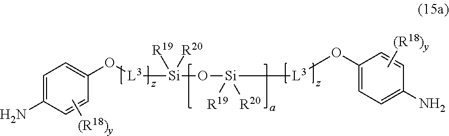

wherein
R¹⁸ is halogen or O—C₁₋₁₀-alkyl,
R¹⁹ and R²⁰ are the same and different and are C₁₋₁₀-alkyl, C₁₋₁₀-haloalkyl or C₄₋₈-cycloalkyl or phenyl,
L³ is C₁₋₁₀-alkylene or phenylene
y is 0, 1, 2, 3 or 4
z is 0 or 1
a is 0 or an integer from 1 to 50, preferably 0 or an integer from 1 to 25,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Preferred diamines of formula (15a) are the diamines of formulae

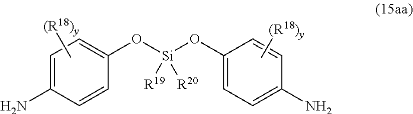

wherein
R¹⁸ is halogen or O—C₁₋₁₀-alkyl,
R¹⁹ and R²⁰ are the same and different and are C₁₋₁₀-alkyl, C₄₋₈-cycloalkyl or phenyl,
y is 0, 1, 2, 3 or 4
and

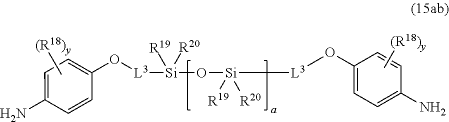

wherein
R¹⁸ is halogen or O—C₁₋₁₀-alkyl,
R¹⁹ and R²⁰ are the same and different and are C₁₋₁₀-alkyl, C₄₋₈-cyclobutyl or phenyl
L³ is C₁₋₁₀-alkylene or phenylene,
a is 0 or an integer from 1 to 50, preferably 0 or an integer from 1 to 25,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

Examples of diamines of formula (15aa) are

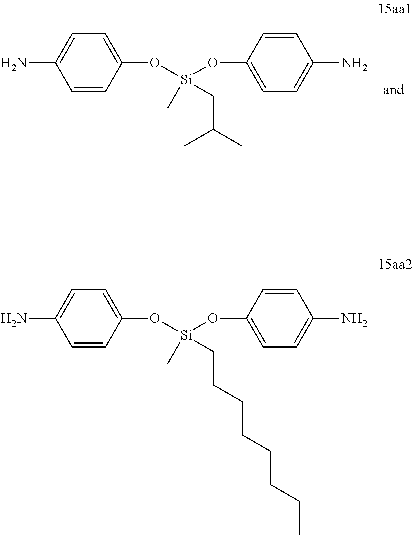 [SMILES: CC(C)C[Si](C)(Oc1ccc(N)cc1)Oc1ccc(N)cc1 ; CCCCCCCC[Si](C)(Oc1ccc(N)cc1)Oc1ccc(N)cc1]

An example of a diamine of formula (15ab) is

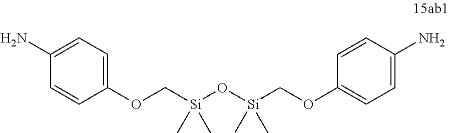 [SMILES: C[Si](C)(COc1ccc(N)cc1)O[Si](C)(C)COc1ccc(N)cc1]

Diamines of formula (15) are either commercially available or can be prepared by methods known in the art, for example diamines of formula (15aa) can be prepared as described by Ismail, R. M. Helv. Chim. Acta 1964, 47, 2405 to 2410, examples 12 to 14, for example diamines of formula (15ab) can be prepared as described in EP 0 054 426 A2, for example in examples XXVI and XXVIII.

Preferred diamines of formula (16) are the diamines of formulae

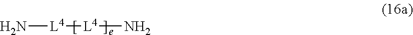

wherein
e is 0
L⁴ is C₁₋₁₀-alkylene, C₄₋₈-cycloalkylene or C₄₋₈-cycloalkylene-Z—C₄₋₈-cycloalkylene,
wherein Z is a direct bond, C₁₋₁₀-alkylene or O,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.
and

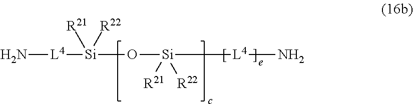

wherein
R²¹ and R²² are the same and different and are C₁₋₁₀-alkyl,
L⁴ is C₁₋₁₀-alkylene, C₄₋₈-cycloalkylene or C₄₋₈-cycloalkylene-Z—C₄₋₈-cycloalkylene,
wherein Z is C₁₋₁₀-alkylene or O,
e is 1
c is 0 or an integer from 1 to 50, preferably, 0 or an integer from 1 to 25, more preferably 0 or an integer from 1 to 6, most preferably 0 or 1,
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

An example of a diamine of formula (16a) is

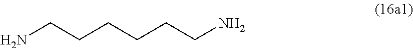

Examples of diamines of formula (16b) are

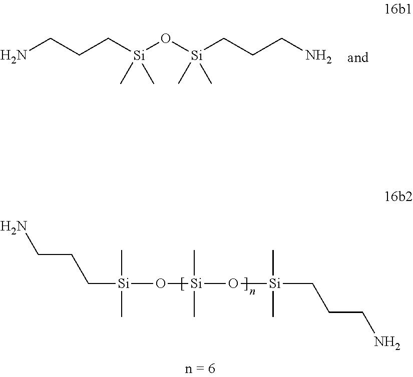

In preferred diamines of formula (16a)

e is 0
L⁴ is C₁₋₄-alkylene, which C₁₋₄-alkylene can be optionally substituted with one or more C₁₋₁₀-alkyl, C₁₋₁₀-haloalkyl and/or C₄₋₈-cycloalkyl.

In more preferred diamines of formula (16a)

e is 0
L⁴ is C₁₋₄-alkylene.

The most preferred diamine of formula (16a) is

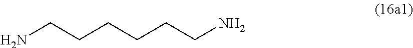

In preferred diamines of formula (16b)

e is 1
R²¹ and R²² are the same and different and are C₁₋₁₀-alkyl,
L⁴ is C₁₋₁₀-alkylene,
c is 0 or an integer from 1 to 6
wherein C₁₋₁₀-alkylene can be optionally substituted with one or more C₁₋₁₀-alkyl, C₁₋₁₀-haloalkyl and/or C₄₋₈-cycloalkyl, or interrupted by O or S.

In more preferred diamines of formula (16b) wherein

e is 1
R²¹ and R²² are the same and different and are C₁₋₄-alkyl
L⁴ is C₁₋₄-alkylene

c is 0 or 1

wherein C₁₋₁₀-alkylene can be optionally substituted with one or more C₁₋₁₀-alkyl, C₁₋₁₀-haloalkyl and/or C₄₋₈-cycloalkyl, or interrupted by —O—.

In most preferred diamines of formula (16b) the diamine of formula

e is 1
R²¹ and R²² are the same and different and are C₁₋₄-alkyl
L⁴ is C₁₋₄-alkylene
c is 1

The most preferred diamine of formula (16b) is the diamine of formula

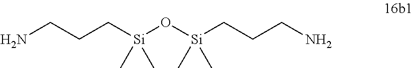

Diamines of formula (16) are either commercially available or can be prepared by methods known in the art, for example the diamine of formula (16b1) is commercially available.

The mixture of reactants may further comprise at least one dianhydride C and/or at least one diamine C, wherein the dianhydride C can be any dianhydride different from dianhydride A and dianhydride B, and the diamine C can be any diamine different from diamine A and diamine B.

The dianhydride C is an organic compound carrying two —C(O)—O—C(O)— functionalities.

Preferably, dianhydride C is an organic compound containing at least one aromatic ring and carrying two —C(O)—O—C(O)— functionalities, wherein the two —C(O)—O—C(O)— functionalities are attached to the same or different aromatic rings.

The diamine C is an organic compound carrying two amino functionalities.

Preferably, the mixture of reactants does not comprise a dianhydride, which is an organic compound carrying two —C(O)—O—C(O)— functionalities, wherein the two —C(O)—O—C(O)— functionalities are attached to an aliphatic residue.

Examples of aliphatic residues are alicyclic rings, alkyl or alkylene residue.

Examples of alicyclic rings are C₄₋₈-cycloalkyl, C₄₋₈-cycloalkenyl and C₄₋₈-cycloalkylene.

Examples of alkyl are C₁₋₁₀-alkyl. Examples of alkylene are C₁₋₁₀-alkylene.

In particular, the mixture of reactants does not comprise a dianhydride selected from the group consisting of

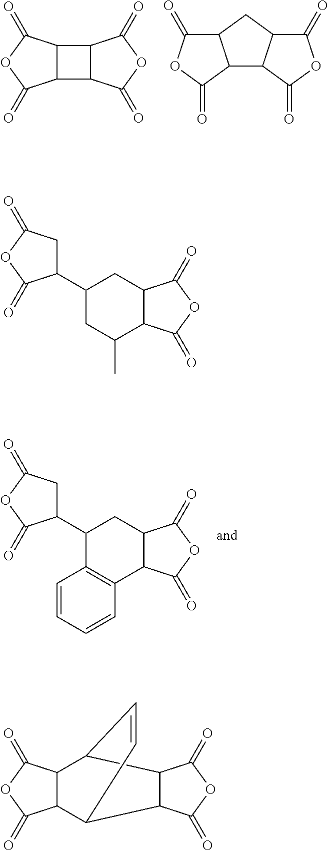

The mixture of reactants may comprise

from 0.1 to 100% by mol of all dianhydride A based on the sum of moles of all dianhydrides A and B and C
from 0 to 99% by mol of all dianhydride B based on the sum of moles of all dianhydrides A and B and C
from 0 to 99% by mol of all dianhydride C based on the sum of moles of all dianhydrides A and B and C
from 0.1 to 100% by mol of all diamine A based on the sum of moles of all diamines A and B and C
from 0 to 99% by mol of all diamine B based on the sum of moles of all diamines A and B and C
from 0 to 99% by mol of all diamine C based on the sum of moles of all diamines A and B and C,
wherein molar ratio of (dianhydride A and dianhydride B and dianhydride C)/(diamine A and diamine B and diamine C) is in the range of 150/100 to 100/150, preferably, in the range of 130/100 to 100/70, more preferably in the range of 120/100 to 100/80, and most preferably, in the range of 110/100 to 100/90.

Preferably, the mixture of reactants comprises

from 20 to 100% by mol of all dianhydride A based on the sum of moles of all dianhydrides A and B and C
from 0 to 80% by mol of all dianhydride B based on the sum of moles of all dianhydrides A and B and C
from 0 to 80%, by mol of all dianhydride C based on the sum of moles of all dianhydrides A and B and C
from 20 to 100%, by mol of all diamine A based on the sum of moles of all diamines A and B and C
from 0 to 80% by mol of all diamine B based on the sum of moles of all diamines A and B and C
from 0 to 80% by mol of all diamine C based on the sum of moles of all diamines A and B and C,
wherein molar ratio of (dianhydride A and dianhydride B and dianhydride C)/(diamine A and diamine B and diamine C) is in the range of 130/100 to 100/70, more preferably in the range of 120/100 to 100/80, and most preferably, in the range of 110/100 to 100/90.

The mixture of reactants can essentially consist of

from 0.1 to 100% by mol of all dianhydride A based on the sum of moles of all dianhydrides A and B and C
from 0 to 99% by mol of all dianhydride B based on the sum of moles of all dianhydrides A and B and C
from 0 to 99% by mol of all dianhydride C based on the sum of moles of all dianhydrides A and B and C
from 0.1 to 100% by mol of all diamine A based on the sum of moles of all diamines A and B and C
from 0 to 99% by mol of all diamine B based on the sum of moles of all diamines A and B and C
from 0 to 99% by mol of all diamine C based on the sum of moles of all diamines A and B and C,
wherein molar ratio of (dianhydride A and dianhydride B and dianhydride C)/(diamine A and diamine B and diamine C) is in the range of 150/100 to 100/150, preferably, in the range of 130/100 to 100/70, more preferably in the range of 120/100 to 100/80, and most preferably, in the range of 110/100 to 100/90.

Preferably, the mixture of reactants essentially consists of

from 20 to 100% by mol of all dianhydride A based on the sum of moles of all dianhydrides A and B and C
from 0 to 80% by mol of all dianhydride B based on the sum of moles of all dianhydrides A and B and C
from 0 to 80%, by mol of all dianhydride C based on the sum of moles of all dianhydrides A and B and C
from 20 to 100%, by mol of all diamine A based on the sum of moles of all diamines A and B and C
from 0 to 80% by mol of all diamine B based on the sum of moles of all diamines A and B and C
from 0 to 80% by mol of all diamine C based on the sum of moles of all diamines A and B and C,
wherein molar ratio of (dianhydride A and dianhydride B and dianhydride C)/(diamine A and diamine B and diamine C) is in the range of 130/100 to 100/70, more preferably in the range of 120/100 to 100/80, and most preferably, in the range of 110/100 to 100/90.

The glass temperature of the photocurable polyimide A is preferably above 150° C., more preferably above 170° C., and more preferably between 170° C. and 300° C.

The molecular weight of the photocurable polyimide A can be in the range of 5,000 to 1,000,000 g/mol, preferably, in the range of 5,000 to 40,000 g/mol, most preferably in the range of 5,000 to 20,000 g/mol (as determined by gel permeation chromatography).

In polyimide A, the substituents on the aromatic rings preferably are located in orthoposition relative to nitrogen. Thus, an especially preferred polyimide A corresponds to the following formula (II):

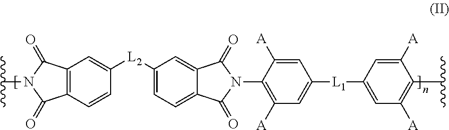

wherein
n ranges from about 10 to 100, especially from 10 to 50;
L₁ independently is O, S, phenylene or C(O), especially C₁-C₃alkylene such as CH₂;
L₂ independently is selected from carbonyl, oxygen, sulphur; especially carbonyl; and each A independently is selected from hydrogen and C1-C4alkyl, provided that at least 2.5% of the residues A, especially 5 to 95% of the residues A in the polyimide A are propyl or butyl, especially isopropyl or isobutyl or sec.butyl or tert.butyl; most especially isopropyl.

The propyl and/or butyl substituted moiety usually makes up at least 5% of the monomer moieties in polyimide A, preferred is a percentage of about 10 to 55% of all monomer moieties in polyimide A. Of special industrial importance is the polyamide A, wherein the propyl and/or butyl substituted ring is part of the diamine moiety, making up about 5 to 95 mol-%, especially about 10 to 90 mol-% of the diamine moieties (such as the diamine core in the above structure I). The remaining diamine moieties may be unsubstituted (e.g. all A of structure II being H) or preferably substituted by methyl and/or ethyl (e.g. at least one A of structure II being methyl or ethyl). Polyimide A preferably is photocurable.

Preferably, polyimide A is applied as a solution in an organic solvent A onto the layer of the device (e.g. transistor, semiconductor layer, electrode etc.) or directly on the substrate.

The organic solvent A can be any solvent (or solvent mixture) that can dissolve at least 2% by weight, preferably at least 5% by weight, more preferably, at least 8% by weight of the photocurable polyimide A based on the weight of the solution of photocurable polyimide A.

As the organic solvent A, generally any solvent may be chosen which has a boiling point (at ambient pressure) from the range of about 80 to 250° C. Solvent A may be a mixture of such solvents. In a preferred process, any component of solvent A has a boiling point from the range 100-220° C., especially 100-200° C. Also of importance are blends using a main solvent (e.g. 70% b.w. or more, such as 95%) having a boiling point around 150° C. (e.g. 120 to 180° C.) and a minor component (30% b.w. or less, such as 5%) having a high boiling point of more than 200° C., e.g. from the range 200-250° C.

Preferably, the organic solvent A is selected from the group consisting of N-methylpyrrolidone, C₄₋₈-cycloalkanone, C₁₋₄-alkyl-C(O)—C₁₋₄-alkyl, C₁₋₄-alkanoic acid C₁₋₄-alkyl ester, wherein the C₁₋₄-alkyl or the C₁₋₄-alkanoic acid can be substituted by hydroxyl or O—C₁₋₄-alkyl, and C₁₋₄-alkyl-O—C₁₋₄-alkylene-O—C₁₋₄-alkylene-O—C₁₋₄-alkyl, and mixtures thereof.

Examples of C₁₋₄-alkyl-C(O)—C₁₋₄-alkyl are ethyl isopropyl ketone, methyl ethyl ketone and methyl isobutyl ketone.

Examples of C₁₋₄-alkanoic acid C₁₋₄-alkyl ester, wherein the C₁₋₄-alkyl or the C₁₋₄-alkanoic acid can be substituted by hydroxyl or O—C₁₋₄-alkyl, are ethyl acetate, butyl acetate, isobutyl acetate, (2-methoxy)ethyl acetate, (2-methoxy)propyl acetate and ethyl lactate.

An example of C₁₋₄-alkyl-O—C₁₋₄-alkylene-O—C₁₋₄-alkylene-O—C₁₋₄-alkyl is diethyleneglycoldimethylether.

More preferably, the organic solvent A is selected from the group consisting of C₄₋₈-cycloalkanone, C₁₋₄-alkyl-C(O)—C₁₋₄-alkyl, C₁₋₄-alkanoic acid C₁₋₄-alkyl ester, wherein the C₁₋₄-alkyl or the C₁₋₄-alkanoic acid can be substituted by hydroxyl or O—C₁₋₄-alkyl, and C₁₋₄-alkyl-O—C₁₋₄-alkylene-O—C₁₋₄-alkylene-O—C₁₋₄-alkyl, and mixtures thereof. Examples are methyl ethyl ketone (b.p. 80° C.), 1,4-dioxane, methyl-isobutyl ketone, butylacetate, 2-hexanone, 3-hexanone, 2-methoxy-1,3-dioxolane, Propylene glycol methyl ether acetate (PGMEA), ethyl lactate, DiGlyme, 5-methyl-3H-furan-2-one (b.p. 169° C. [“alpha-angelica lactone”]), dipropylene glycol dimethyl ether (b.p. 175° C. [ProGlyde DMM]), N-methylpyrrolidone (NMP), gamma-butyrolactone, acetophenone, isophorone, gamma-aprolactone, 1,2-propylene carbonate (b.p. 241° C.); blends of Propylene glycol methyl ether acetate (PGMEA, b.p. 145° C., e.g. 95%) and propylene carbonate (e.g. 5%).

Most preferably, the organic solvent A is selected from the group consisting of C₅₋₆-cycloalkanone, C₁₋₄-alkanoic acid C₁₋₄-alkyl ester, and mixtures thereof. Even most preferably the organic solvent A is cyclopentanone or butyl acetate or mixtures thereof. In particular preferred organic solvents A are butyl acetate or mixtures of butyl acetate and pentanone, wherein the weight ratio of butyl acetate/cyclopentane is at least from 99/1 to 20/80, more preferably from 99/1 to 30/70.

If the photocurable polyimide A is applied as a solution in an organic solvent A on the layer of the transistor or on the substrate, the photocurable polyimide A can be applied by any possible solution process, such as spin-coating, drop-casting or printing.

After applying photocurable polyimide A as a solution in an organic solvent A on the layer of the transistor or on the substrate, a heat treatment at a temperature of below 140° C., for example at a temperature in the range of 60 to 120° C., preferably at a temperature of below 120° C., for example in the range of 60 to 110° C. can be performed.

The layer comprising photocurable polyimide A can have a thickness in the range of 100 to 1000 nm, preferably, in the range of 300 to 1000 nm, more preferably 300 to 700 nm.

The layer comprising photocurable polyimide A can comprise from 50 to 100% by weight, preferably from 80 to 100%, preferably 90 to 100% by weight of photocurable polyimide A based on the weight of the layer comprising photocurable polyimide A. Preferably, the layer comprising photocurable polyimide A essentially consists of photocurable polyimide A.

The layer comprising photocurable polyimide A can be irradiated with any suitable light source providing UV light (e.g. of wavelength 250-400 nm) or light of a wavelength of 360 nm or more (e.g. 360-440 nm), for example with an LED lamp, in order to form the layer comprising polyimide B.

The layer comprising polyimide B can comprise from 50 to 100% by weight, preferably from 80 to 100%, preferably 90 to 100% by weight of polyimide B based on the weight of the layer comprising polyimide B. Preferably, the layer comprising polyimide B essentially consists of polyimide B.

The layer comprising photocurable polyimide B can have a thickness in the range of 100 to 1000 nm, preferably, in the range of 300 to 1000 nm, more preferably 300 to 700 nm.

The irradiation of the layer comprising photocurable polyimide A with UV light (e.g. of wavelength 250-400 nm) or light of a wavelength of 320 nm or more (e.g. 360-440 nm) in order to form the cured layer comprising polyimide B may be performed on only part of the layer comprising photocurable polyimide A, for example by using a mask. If the irradiation performed on only part of the layer comprising photocurable polyimide A, the non-irradiated part of the polyimide may be removed by dissolving it in an organic solvent B, leaving behind a patterned layer comprising polyimide B.

The organic solvent B may be any solvent (or solvent mixture) that can dissolve at least 2% by weight, preferably at least 5% by weight, more preferably, at least 8% by weight of the photocurable polyimide A based on the weight of the solution of photocurable polyimide A.

The organic solvent B advantageously is selected from solvents (or solvent mixtures) having a boiling point (at ambient pressure) of below 180° C., preferably below 150° C., more preferably below 130° C.

Preferably, the organic solvent B is selected from the group consisting of N-methylpyrrolidone, C₄₋₈-cycloalkanone, C₁₋₄-alkyl-C(O)—C₁₋₄-alkyl, C₁₋₄-alkanoic acid C₁₋₄-alkyl ester, wherein the C₁₋₄-alkyl or the C₁₋₄-alkanoic acid can be substituted by hydroxyl or O—C₁₋₄-alkyl, and C₁₋₄-alkyl-O—C₁₋₄-alkylene-O—C₁₋₄-alkylene-O—C₁₋₄-alkyl, and mixtures thereof.

After dissolving the non-irradiated part of photocurable polyimide A in an organic solvent B, a heat treatment at a temperature of below 140° C., for example at a temperature in the range of 60 to 120° C., preferably at a temperature of below 120° C., for example in the range of 60 to 110° C. can be performed.

The transistor on a substrate is preferably a field-effect transistor (FET) on a substrate and more preferably an organic field-effect transistor (OFET) on a substrate.

Usually, an organic field effect transistor comprises a dielectric layer and a semiconducting layer. In addition, on organic field effect transistor usually comprises a gate electrode and source/drain electrodes.

Typical designs of organic field effect transistors are the Bottom-Gate design and the Top-Gate design:

In case of the Bottom-Gate Bottom-Contact (BGBC) design, the gate is on top of the substrate and at the bottom of the dielectric layer, the semiconducting layer is at the top of the dielectric layer and the source/drain electrodes are on top of the semiconducting layer (see typical process in FIG. 7).

Another design of a field-effect transistor on a substrate is the Top-Gate Bottom-Contact (TGBC) design: The source/drain electrodes are on top of the substrate and at the bottom of the semiconducting layer, the dielectric layer is on top of the disemiconducting layer and the gate electrode is on top of the dielectric layer. When prepared by solution processing, here the solvents used for dielectrics must be fully orthogonal with respect to the semiconductor (i.e. show good solubility of the dielectric and absolute insolubility of the semiconductor), and additionally compatible with photoresist processing (typically as shown in FIG. 8, critical stages highlighted by circles).

The semiconducting layer comprises a semiconducting material. Examples of semiconducting materials are semiconducting materials having p-type conductivity (carrier: holes) and semiconducting materials having n-type conductivity (carrier: electrons).

Examples of semiconductors having n-type conductivity are perylenediimides, naphtalenediimides and fullerenes.

Semiconducting materials having p-type conductivity are preferred. Examples of semiconducting materials having p-type conductivity are molecules such as as rubrene, tetracene, pentacene, 6,13-bis(triisopropylethynyl) pentacene, diindenoperylene, perylenediimide and tetracyanoquinodimethane, and polymers such as polythiophenes, in particular poly 3-hexylthiophene (P3HT), polyfluorene, polydiacetylene, poly 2,5-thienylene vinylene, poly p-phenylene vinylene (PPV) and polymers comprising repeating units having a diketopyrrolopyrrole group (DPP polymers).

Preferably the semiconducting material is a polymer comprising units having a diketopyrrolopyrrole group (DPP polymer).

Examples of DPP polymers and their synthesis are, for example, described in U.S. Pat. No. 6,451,459 B1, WO 2005/049695, WO 2008/000664, WO 2010/049321, WO 2010/049323, WO 2010/108873, WO 2010/115767, WO 2010/136353 and WO 2010/136352.

Preferably, the DPP polymer comprises, preferably essentially consists, of a unit selected from the group consisting of

a polymer unit of formula

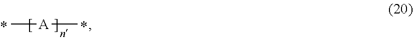

a copolymer unit of formula

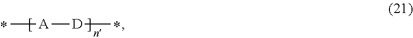

a copolymer unit of formula

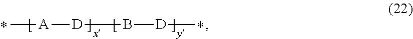

and
a copolymer unit of formula

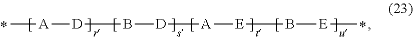

wherein
n′ is 4 to 1000, preferably 4 to 200, more preferably 5 to 100,
x′ is 0.995 to 0.005, preferably x′ is 0.2 to 0.8,
y′ is 0.005 to 0.995, preferably y′ is 0.8 to 0.2, and
x′+y′=1;
r′ is 0.985 to 0.005,
s′ is 0.005 to 0.985,
t′ is 0.005 to 0.985,
u′ is 0.005 to 0.985, and
r′+s′+t′+u′=1;

A is a group of formula

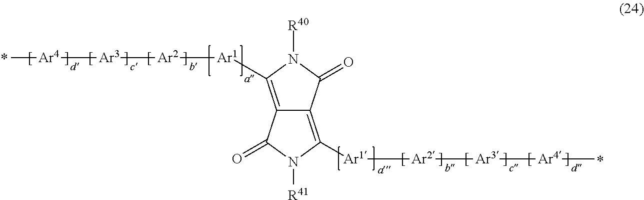

wherein
a″ is 1, 2, or 3,
a′″ is 0, 1, 2, or 3,
b′ is 0, 1, 2, or 3,
b″ is 0, 1, 2, or 3,
c′ is 0, 1, 2, or 3,
c″ is 0, 1, 2, or 3,
d′ is 0, 1, 2, or 3,
d″ is 0, 1, 2, or 3,
with the proviso that b″ is not 0, if a′″ is 0;
R⁴⁰ and R⁴¹ are the same or different and are selected from the group consisting of hydrogen, C₁-C₁₀₀alkyl, —COOR^{106″}, C₁-C₁₀₀alkyl which is substituted with one or more halogen, hydroxyl, nitro, —CN, or C₆-C₁₈aryl and/or interrupted by —O—, —COO—, —OCO—, or —S—; C₇-C₁₀₀arylalkyl, carbamoyl, C₅-C₁₂cycloalkyl, which can be substituted one to three times with C₁-C₈alkyl and/or C₁-C₈alkoxy, C₆-C₂₄aryl, in particular phenyl or 1- or 2-naphthyl which can be substituted one to three times with C₁-C₈alkyl, C₁-C₂₅thioalkoxy, and/or C₁-C₂₅alkoxy, or pentafluorophenyl, wherein
   R^{106″} is C₁-C₅₀alkyl, preferably C₄-C₂₅alkyl,
Ar¹, Ar^{1′}, Ar², Ar^{2′}, Ar³, Ar^{3′}, Ar⁴ and Ar^{4′} are independently of each other heteroaromatic, or aromatic rings, which optionally can be condensed and/or substituted, preferably

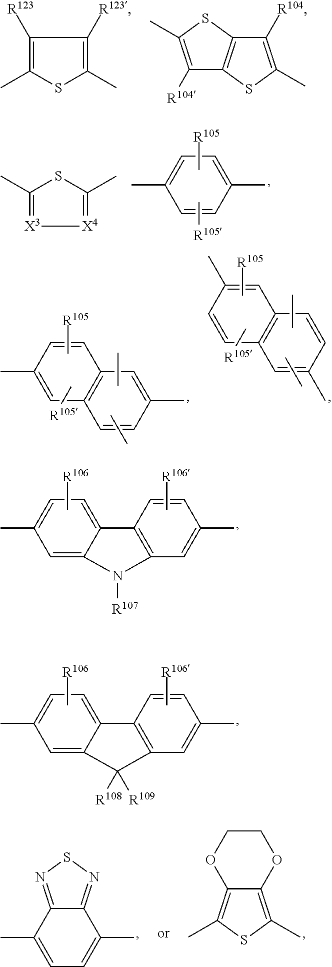

wherein
one of X³ and X⁴ is N and the other is CR⁹⁹,
   wherein R⁹⁹ is hydrogen, halogen, preferably F, or C₁-C₂₅alkyl, preferably a C₄-C₂₅alkyl, which may optionally be interrupted by one or more oxygen or sulphur atoms, C₇-C₂₅arylalkyl, or C₁-C₂₅alkoxy,
R¹⁰⁴, R^{104′}, R¹²³ and R^{123′} are independently of each other hydrogen, halogen, preferably F, or C₁-C₂₅alkyl, preferably a C₄-C₂₅alkyl, which may optionally be interrupted by one or more oxygen or sulphur atoms, C₇-C₂₅arylalkyl, or C₁-C₂₅alkoxy,
R¹⁰⁵, R^{105′}, R¹⁰⁶ and R^{106′} are independently of each other hydrogen, halogen, C₁-C₂₅alkyl, which may optionally be interrupted by one or more oxygen or sulphur atoms; C₇-C₂₅arylalkyl, or C₁-C₁₈alkoxy,
R¹⁰⁷ is C₇-C₂₅arylalkyl, C₆-C₁₈aryl; C₆-C₁₈aryl which is substituted by C₁-C₁₈alkyl, C₁-C₁₈perfluoroalkyl, or C₁-C₁₈alkoxy; C₁-C₁₈alkyl; C₁-C₁₈alkyl which is interrupted by —O—, or —S—; or —COOR¹²⁴;
   R¹²⁴ is C₁-C₂₅alkyl, preferably C₁-C₂₅alkyl, which may optionally be interrupted by one or more oxygen or sulphur atoms, C₇-C₂₅arylalkyl,
R¹⁰⁸ and R¹⁰⁹ are independently of each other H, C₁-C₂₅alkyl, C₁-C₂₅alkyl which is substituted by E′ and/or interrupted by D′, C₇-C₂₅arylalkyl, C₆-C₂₄aryl, C₆-C₂₄aryl which is substituted by G, C₂-C₂₀heteroaryl, C₂-C₂₀heteroaryl which is substituted by G, C₂-C₁₆alkenyl, C₂-C₁₈alkynyl, C₁-C₁₈alkoxy, C₁-C₁₈alkoxy which is substituted by E′ and/or interrupted by D′, or C₇-C₂₅aralkyl,
or
R¹⁰⁸ and R¹⁰⁹ together form a group of formula ═CR¹¹⁰R¹¹¹, wherein
   R¹¹⁰ and R¹¹¹ are independently of each other H, C₁-C₁₈alkyl, C₁-C₁₈alkyl which is substituted by E′ and/or interrupted by D′, C₆-C₂₄aryl, C₆-C₂₄aryl which is substituted by G, or C₂-C₂₀heteroaryl, or C₂-C₂₀heteroaryl which is substituted by G,
or
R¹⁰⁸ and R¹⁰⁹ together form a five or six membered ring, which optionally can be substituted by C₁-C₁₈alkyl, C₁-C₁₈alkyl which is substituted by E′ and/or interrupted by D′, C₆-C₂₄aryl, C₆-C₂₄aryl which is substituted by G, C₂-C₂₀heteroaryl, C₂-C₂₀heteroaryl which is substituted by G, C₂-C₁₈alkenyl, C₂-C₁₈alkynyl, C₁-C₁₈alkoxy, C₁-C₁₈alkoxy which is substituted by E′ and/or interrupted by D′, or C₇-C₂₅aralkyl, wherein
   D′ is —CO—, —COO—, —S—, —O—, or —NR₁₁₂—,
   E′ is C₁-C₈thioalkoxy, C₁-C₈alkoxy, CN, —NR¹¹²R¹¹³, or halogen,
   G is E′, or C₁-C₁₈alkyl, and
      R¹¹² and R¹¹³ are independently of each other H; C₆-C₁₈aryl; C₆-C₁₈aryl which is substituted by C₁-C₁₈alkyl, or C₁-C₁₈alkoxy; C₁-C₁₈alkyl; or C₁-C₁₈alkyl which is interrupted by —O— and
         B, D and E are independently of each other a group of formula

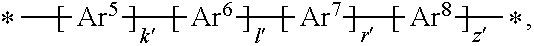

or a group of formula (24),
with the proviso that in case B, D and E are a group of formula (24), they are different from A, wherein
k′ is 1,
l′ is 0, or 1,
r′ is 0, or 1,
z′ is 0, or 1, and
Ar⁵, Ar⁶, Ar⁷ and AO are independently of each other a group of formula

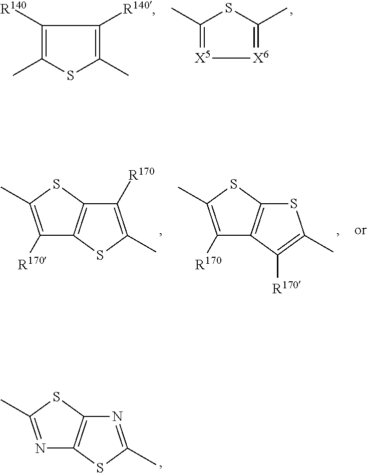

wherein one of X⁵ and X⁶ is N and the other is CR¹⁴⁰,
R¹⁴⁰, R^{140′}, R¹⁷⁰ and R^{170′} are independently of each other H, or a C₁-C₂₅alkyl, preferably C₆-C₂₅alkyl, which may optionally be interrupted by one or more oxygen atoms.

Preferred polymers are described in WO2010/049321.

Ar¹ and Ar^{1′} are preferably

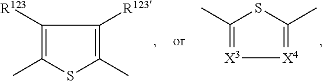

very preferably

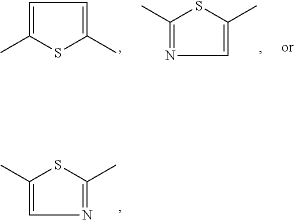

and most preferably

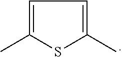

Ar², Ar^{2′}, Ar³, Ar^{3′}, Ar⁴ and Ar^{4′} are preferably

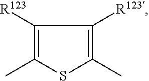

more preferably

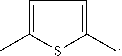

The group of formula

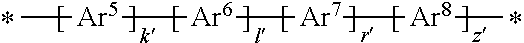

is preferably

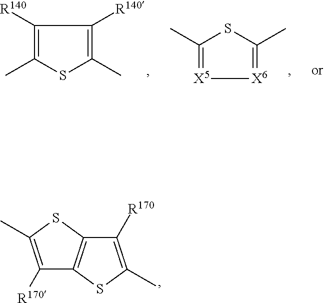

more preferably

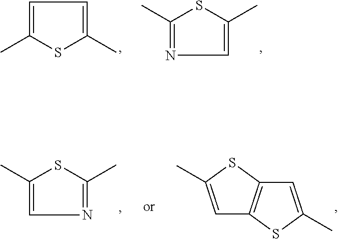

most preferred

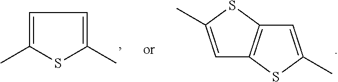

R⁴⁰ and R⁴¹ are the same or different and are preferably selected from hydrogen, C₁-C₁₀₀alkyl, more preferably a C₈-C₃₆alkyl.

A is preferably selected from the group consisting of

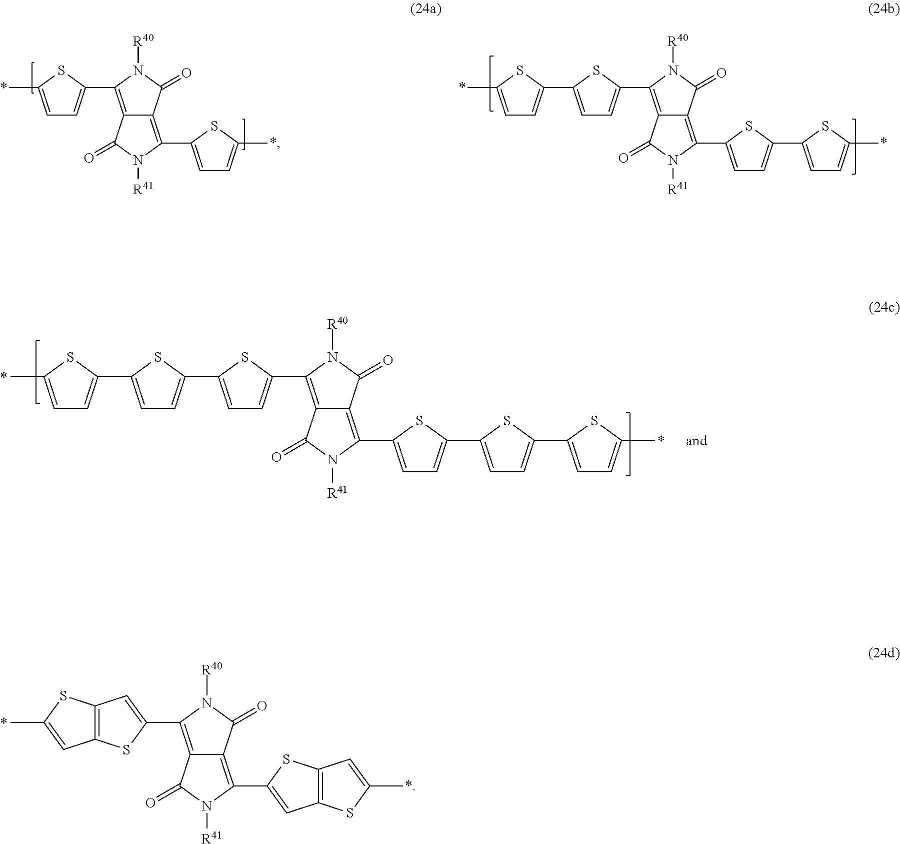

Examples of preferred DPP polymers comprising, preferably consisting essentially of, a polymer unit of formula (20) are shown below:

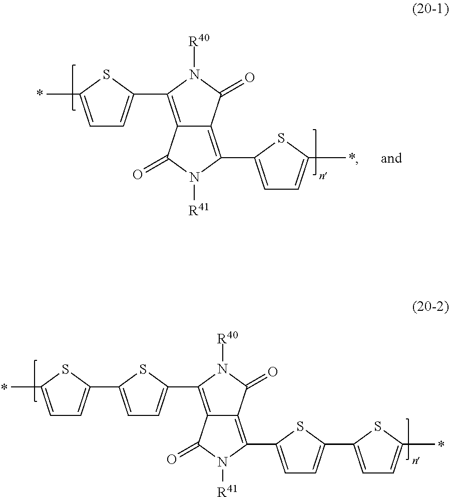

wherein
R⁴⁰ and R⁴¹ are C₁-C₃₆alkyl, preferably C₈-C₃₆alkyl, and
n′ is 4 to 1000, preferably 4 to 200, more preferably 5 to 100.

Examples of preferred DPP polymers comprising, preferably consisting essentially of, a copolymer unit of formula (21) are shown below:

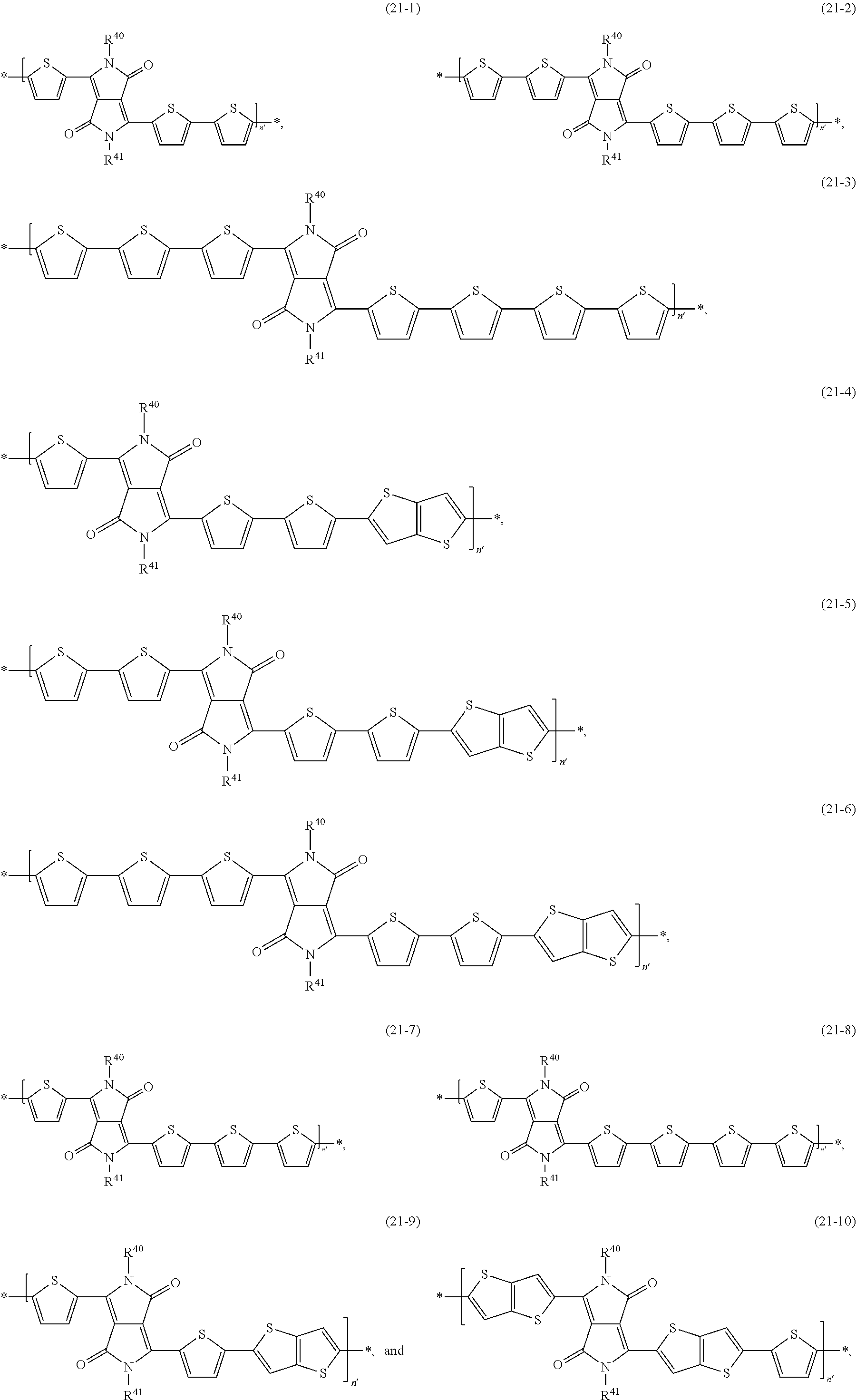

wherein
R⁴⁰ and R⁴¹ are C₁-C₃₆alkyl, preferably C₈-C₃₆alkyl, and
n′ is 4 to 1000, preferably 4 to 200, more preferably 5 to 100.

Examples of preferred DPP polymers comprising, preferably essentially consisting of, a copolymer unit of formula (22) are shown below:

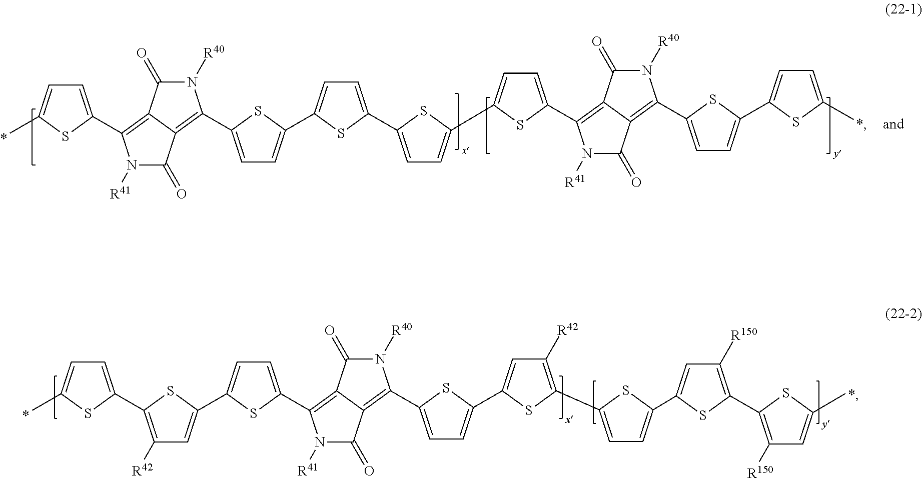

wherein
R⁴⁰ and R⁴¹ are C₁-C₃₆alkyl, preferably C₈-C₃₆alkyl,
R⁴² is C₁-C₁₈alkyl,
R¹⁵⁰ is a C₄-C₁₈alkyl group,
X′=0.995 to 0.005, preferably x′=0.4 to 0.9,
y′=0.005 to 0.995, preferably y′=0.6 to 0.1, and
x+y=1.

DPP Polymers comprising, preferably consisting essentially of, a copolymer unit of formula (22-1) are more preferred than DPP polymers comprising, preferably consisting essentially of, a copolymer unit of formula (22-2).

The DPP polymers preferably have a weight average molecular weight of 4,000 Daltons or greater, especially 4,000 to 2,000,000 Daltons, more preferably 10,000 to 1,000,000 and most preferably 10,000 to 100,000 Daltons.

DPP Polymers comprising, preferably consisting essentially of, a copolymer unit of formula (21-1) are particularly preferred. Reference is, for example made to example 1 of WO2010/049321:

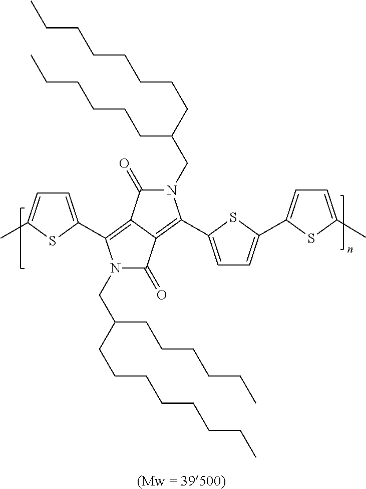

The dielectric layer comprises a dielectric material. The dielectric material can be silicium/silicium dioxide, or, preferably, an organic polymer such as poly(methylmethacrylate) (PMMA), poly(4-vinylphenol) (PVP), poly(vinyl alcohol) (PVA), anzocyclobutene (BCB), and polyimide (PI).

Preferably the layer comprising the polyimide B is the dielectric layer.

The substrate can be any suitable substrate such as glass, or a plastic substrate. Preferably the substrate is a plastic substrate such as polyethersulfone, polycarbonate, polysulfone, polyethylene terephthalate (PET) and polyethylene naphthalate (PEN). More preferably, the plastic substrate is a plastic foil.

Also part of the invention is a transistor obtainable by above process.

The advantage of the process for the preparation of a transistor, preferably an organic field effect transistor comprising a layer comprising polyimide B, for example as dielectric layer, is that all steps of the process, and in particular the step of forming the layer comprising the photocurable polyimide A, can be performed at a temperatures below 160° C., preferably below 150°, more preferably below 120° C.

Another advantage of the process of the present invention is that the photocurable polyimide A used is resistant to shrinkage.

Another advantage of the process of the present invention is that the photocurable polyimide A preferably has a glass temperature of at least 150° C., preferably of at least 170° C. Thus, photocurable polyimide A and polyimide B (derived from photocurable polyimide A) show a high chemical and thermal stability. As a consequence, the process of the present invention can be used to prepare, for example, an organic field effect transistor, wherein the layer comprising polyimide B is the dielectric layer, wherein the electrodes on top of the dielectric layer can be structured by an etching process.

Another advantage of the process of the present invention is that the photocurable polyimide A allows the formation of patterns.

Another advantage of the process of the present invention is that photocurable polyimide A is soluble in an organic solvent (solvent A). Preferably, it is possible to prepare a 2% by weight, more preferably a 5% by weight and most preferably a 8% by weight solution of photocurable polyimide A in the organic solvent. Thus, it is possible to apply photocurable polyimide A by solution processing techniques.

Another advantage of the process of the present invention is that the organic solvent used to dissolve photocurable polyimide A
(i) preferably has a boiling point (at ambient pressure) of below 160° C., preferably below 150° C., more preferably below 120° C., and thus can be can be removed by heat treatment at a temperature of below 120° C., preferably at a temperature in the range of 60 to 110° C., and
(ii) preferably does not dissolve suitable semiconducting materials such as diketopyrrolopyrol (DPP) thiophenes, and thus allows the formation of a smooth border when applying the photocurable polyimide A on a semiconducting layer comprising diketopyrrolopyrol (DPP) thiophenes.

Another advantage of the process of the present invention is that all steps of the process can be performed at ambient atmosphere, which means that no special precautions such as nitrogen atmosphere are necessary.

The advantage of the transistor of the present invention, preferably, wherein the transistor is an organic field effect transistor and wherein the layer comprising polyimide B is the dielectric layer and the semiconducting layer comprises a semiconducting material, for example a diketopyrrolopyrrole (DPP) thiophene polymer, is that the transistor shows a high mobility, a high Ion/Ioff ratio and a low gate leakage.

The following examples illustrate the invention. Wherever noted, room temperature (r.t.) depicts a temperature from the range 22-25° C.; over night means a period of 12 to 15 hours; percentages are given by weight, if not indicated otherwise. Molecular weight is as determined by gel permeation chromatography, if not indicated otherwise.

### ABBREVIATIONS

### NMP N-Methylpyrrolidone

BTDA 3,3′,4,4′ Benzophenone-tetracarboxylic acid dianhydride
ODPA oxydiphthalic dianhydride
Tg glass transition temperature
b.p. boiling point (at 1 atmosphere pressure)

### EXAMPLES

### Example 1

### a) Synthesis of Polyimide 62

A 50 ml three-neck flask, equipped with a nitrogen inlet and a mechanical glass stirrer, is flushed with nitrogen and then charged with 4.395 g (10.0 mmol) 4,4′-methylene-bis(2,6-diisopropylaniline) dihydrochloride and 25 ml of anhydrous NMP. After the addition of 2.02 eq. triethylamine to the reaction mixture the colour turns to orange-brown and the reaction mass gets jelly (ammonium salts). After the addition of 3.222 g BTDA (10.0 mmol, 1.0 eq.) the reaction mass is heated to 80° C., stirred for 16 hours at this temperature, then 0.15 g butylamine (0.1 eq., endcapping) are added, stirring is continued for another 6 hours, and then the reaction mixture is cooled to room temperature. After the addition of 3.1 ml of triethylamine and 8.5 ml acetic anhydride, the reaction mixture is stirred for an additional 3 hours and then precipitated in 500 ml water. The polymer is collected by suction filtration, washed with methanol and dried in a vacuum oven at 80° C. for 12 hours. The title polymer is obtained as a creamy coloured powder (6.55 g, 95% yield; Tg=260° C.)).

Further purification can be achieved by ion exchange resins treatment or biphasic extraction processes. Water-free samples can be obtained azeotropic water removal in suited solvents.

When using the free amine of 4,4′-methylene-bis(2,6-diisopropylaniline) in the same synthesis, the resulting polymer remains pink to purple coloured even after several washing and re-precipitation. The resulting photosensitivity of the polymer is lower.

### b) Preparation of Capacitor Comprising a Layer of Polyimide 62

A 8% (weight/weight) solution of polyimide 62 in ethyl lactate/butyl acetate 60/40 (weight/weight) is filtered through a 0.45 μm filter and applied on a clean glass substrate with indium tin oxide (ITO) electrodes by spin coating (2500 rpm, 30 seconds). The wet film is pre-baked at 100° C. for 2 minutes on a hot plate and then photo-cured with a mercury lamp mounted with a filter (wavelength below 320 nm cut, ca. 800 mJ/cm²) to obtain a 500 nm thick layer. Gold electrodes (area=3 mm²) are then vacuum-deposited through a shadow mask on the polyimide 62 layer at <1×10⁻⁶ Torr.

The capacitor thus obtained is characterized in the following way:

The relative permittivity ∈ᵣ and tg(δ)=∈ᵣ″ are deduced from the complex capacity measured with a LCR meter Agilent 4284A (signal amplitude 1 V). Current/Voltage (I/V) curves are obtained with a semiconductor parameter analyser Agilent 4155C. The breakdown voltage is the voltage Ed where the current reaches a value of 1 μA. The volume resistivity p is calculated from the resistance, sample thickness and electrode surface. Results are compiled in table 1.

TABLE 1
Characterization of capacitor containing polyimide 62 layer

| | ρ | εr | εr | εr″ | εr″ | Ed |
|---|---|---|---|---|---|---|
| Polymer | [Ωcm] | 20 Hz | 100 kHz | 20 Hz | 100 kHz | [V/mm] |
| Polyimide 62 | 1.42E+15 | 3.36 | 3.20 | 3.23E−02 | 2.06E−02 | >185 |

### c) Preparation of a Top-Gate, Bottom Contact (TGBC) Field Effect Transistor Comprising a Gate Dielectric Layer of Polyimide 62

Gold is sputtered onto poly(ethylene terephthalate) (PET) foil to form an approximately 40 nm thick film and then source/drain electrodes (channel length: 10 μm; channel width: 10 mm) are structured by photolithography process. A 0.75% (weight/weight) solution of the diketopyrrolopyrrole (DPP)-thiophene-polymer 21-1 (structure identified above) in toluene is filtered through a 0.45 μm polytetrafluoroethylene (PTFE) filter and then applied by spin coating (1300 rpm, 10.000 rpm/s, 15 seconds). The wet organic semi-conducting polymer layer is dried at 100° C. on a hot plate for 30 seconds. A 8% (weight/weight) solution of polyimide 62 in ethyl lactate/butyl acetate 60/40 (weight/weight) is filtered through a 0.45 μm filter and then applied by spin coating (2500 rpm, 30 seconds). The wet polyimide film is pre-baked at 100° C. for 2 minutes on a hot plate and then photo-cured with a mercury lamp mounted with a filter (wavelength below 320 nm cut, about 800 mJ/cm²) to obtain a 500 nm thick layer. Gate electrodes of gold (thickness approximately 120 nm) are evaporated through a shadow mask on the polyimide 62 layer. The whole process is performed without a protective atmosphere.

Measurement of the characteristics of the top gate, bottom contact (TGBC) field effect transistors are measured with a Keithley 2612A semiconductor parameter analyser. The drain current I_{ds} in relation to the gate voltage V_{gs} (transfer curve) for the top-gate, bottom-contact (TGBC) field effect transistor comprising a polyimide 62 gate dielectric at a source voltage V_{sd} of −1V (squares), respectively, −20V (triangles) is shown in FIG. 1.

The top-gate, bottom-contact (TGBC) field effect transistor comprising polyimide 62 shows a mobility of 0.22 cm²/Vs (calculated for the saturation regime) and an Ion/Ioff ratio of 9600.

The drain current I_{ds} in relation to the drain voltage V_{ds} (output curve) for the top-gate, bottom-contact (TGBC) field effect transistor comprising polyimide 62 at a gate voltage V_{gs} of 0V (stars), −5V (squares), −10V (lozenges), −15V (triangles) and −20V (circles) is shown in FIG. 2.

### Example 2

### a) Synthesis of Polyimide 32

A 100 ml three-neck flask, equipped with a nitrogen inlet and a mechanical glass stirrer, is flushed with nitrogen and then charged with 4.395 g (10.0 mmol) 4,4′-methylene-bis(2,6-diisopropylaniline) dihydrochloride and 50 ml anhydrous NMP. After the addition of 2.02 eq. triethylamine the reaction mixture the colour turns to orange-brown and the reaction mass gets jelly (ammonium salts). After the addition of 6.445 g BTDA (20.0 mmol, 2.0 eq.) the reaction mass is heated to 80° C. and stirred until all BTDA is dissolved. After the addition 3,105 g (10.00 mmol) 4,4′-methylene-bis(2,6-diethylaniline) the reaction mixture is stirred for 16 hours at 80° C., then 0.15 g butylamine (0.1 eq., endcapping) are added, stirring is continued for another 6 hours and then the reaction mixture is cooled to room temperature. After the addition of 6.2 ml triethylamine and 17.0 ml acetic anhydride the reaction mixture is stirred for an additional 3 hours and then precipitated in 100 ml water. The polymer is collected by suction filtration, washed with methanol and tert.butylmethyl ether and dried in a vacuum oven at 80° C. for 12 hours. The title polymer is obtained as a creamy coloured powder (11.80 g, 95% yield; Tg=245° C.).

Further purification can be achieved by ion exchange resins treatment or biphasic extraction processes. Water-free samples can be obtained azeotropic water removal in suited solvents.

If the same synthesis is made with the free amine of 4,4′-methylene-bis(2,6-diisopropylaniline) the resulting polymer is pink to purple coloured and even several washing and re-precipitation steps did not produce a “colourless” sample. The resulting photosensitivity of such polymers is lower.

### b) Preparation of Capacitor Comprising a Layer of Polyimide 32

A 15% (weight/weight) solution of polyimide 32 in ethyl lactate/butyl acetate 60/40 (weight/weight) is filtered through a 0.45 μm filter and applied on a clean glass substrate with indium tin oxide (ITO) electrodes by spin coating (2700 rpm, 30 seconds). The wet film is pre-baked at 100° C. for 2 minutes on a hot plate and then photo-cured with a mercury lamp mounted with a filter (wavelength below 320 nm cut, ca.800 mJ/cm²) to obtain a 485 nm thick layer. Gold electrodes (area=3 mm²) are then vacuum-deposited through a shadow mask on the polyimide 32 layer at <1×10⁻⁶ Torr.

The capacitor thus obtained is characterized in the way described in example 1 b. Results are compiled in table 2.

TABLE 2
Characterization of capacitor containing polyimide 32 layer

| | ρ | εr | εr | εr″ | εr″ | Ed |
|---|---|---|---|---|---|---|
| Polymer | [Ωcm] | 20 Hz | 100 kHz | 20 Hz | 100 kHz | [V/mm] |
| Polyimide 32 | 2.21E+15 | 3.08 | 2.99 | 2.38E−02 | 1.08E−02 | 74 |

### c) Preparation of a Top-Gate, Bottom Contact (TGBC) Field Effect Transistor Comprising a Gate Dielectric Layer of Polyimide 32

Gold is sputtered onto poly(ethylene terephthalate) (PET) foil to form an approximately 40 nm thick film and then source/drain electrodes (channel length: 10 μm; channel width: 10 mm) are structured by photolithography process. A 0.75% (weight/weight) solution of the diketopyrrolopyrrole (DPP)-thiophene-polymer 21-1 (see above) in toluene is filtered through a 0.45 μm polytetrafluoroethylene (PTFE) filter and then applied by spin coating (1300 rpm, 10.000 rpm/s, 15 seconds). The wet organic semiconducting polymer layer is dried at 100° C. on a hot plate for 30 seconds. A 15% (weight/weight) solution of polyimide 32 in ethyl lactate/butyl acetate 60/40 (weight/weight) is filtered through a 0.45 μm filter and then applied by spin coating (2700 rpm, 30 seconds). The wet polyimide film is pre-baked at 100° C. for 2 minutes on a hot plate and then photo-cured with a mercury lamp mounted with a filter (wavelength below 320 nm cut, about 800 mJ/cm2) to obtain a 470 nm thick layer. Gate electrodes of gold (thickness approximately 120 nm) are evaporated through a shadow mask on the polyimide 32 layer. The whole process is performed without a protective atmosphere.

Measurement of the characteristics of the top gate, bottom contact (TGBC) field effect transistors are measured with a Keithley 2612A semiconductor parameter analyser. The drain current I_{ds} in relation to the gate voltage V_{gs} (transfer curve) for the top-gate, bottom-contact (TGBC) field effect transistor comprising a polyimide 32 gate dielectric at a source voltage V_{sd} of −1V (squares), respectively, −20V (triangles) is shown in FIG. 3.

The top-gate, bottom-contact (TGBC) field effect transistor comprising polyimide 32 shows a mobility of 0.23 cm²/Vs (calculated for the saturation regime) and an Ion/Ioff ration of 1.6 E+5.

The drain current I_{ds} in relation to the drain voltage V_{ds} (output curve) for the top-gate, bottom-contact (TGBC) field effect transistor comprising polyimide 32 at a gate voltage V_{gs} of 0V (stars), −5V (squares), −10V (lozenges), −15V (triangles) and −20V (circles) is shown in FIG. 4.

### Example 3

### a) Synthesis of Polyimide 08

A 100 ml three-neck flask, equipped with a nitrogen inlet and a mechanical glass stirrer, is flushed with nitrogen and then charged with 4.395 g (10.0 mmol) 4,4′-methylene-bis(2,6-diisopropylaniline) dihydrochloride and 50 ml anhydrous NMP. After the addition of 2.02 eq. triethylamine the reaction mixture the colour turns to orange-brown and the reaction mass gets jelly (ammonium salts). After the addition of 6,204 g ODPA (20.00 mmol, 2 eq,) the reaction mass is heated to 80° C. and stirred until all ODPA is dissolved. After the addition 3,105 g (10.00 mmol) 4,4′-methylene-bis(2,6-diethylaniline) the reaction mixture is stirred for 16 hours at 80° C., then 0.15 g butylamine (0.1 eq., endcapping) are added, stirring is continued for another 6 hours and then the reaction mixture is cooled to room temperature. After the addition of 6.2 ml triethylamine and 17.0 ml acetic anhydride the reaction mixture is stirred for an additional 3 hours and then precipitated in 1000 ml water. The polymer is collected by suction filtration, washed with methanol and tert.butylmethyl ether and dried in a vacuum oven at 80° C. for 12 hours. The title polymer is obtained as a creamy coloured powder (11.80 g, 95% yield).

Further purification can be achieved by ion exchange resins treatment or biphasic extraction processes. Water-free samples can be obtained azeotropic water removal in suited solvents.

If the same synthesis is made with the free amine of 4,4′-methylene-bis(2,6-diisopropylaniline) the resulting polymer is pink to purple coloured and even several washing and re-precipitation steps did not produce a “colourless” sample.

### b) Preparation of Capacitor Comprising a Layer of Polyimide 08

A 10% (weight/weight) solution of polyimide 08 in butyl acetate is filtered through a 0.45 μm filter and applied on a clean glass substrate with indium tin oxide (ITO) electrodes by spin coating (1100 rpm, 30 seconds). The wet film is pre-baked at 100° C. for 2 minutes on a hot plate to obtain a 550 nm thick layer. Gold electrodes (area=3 mm²) are then vacuum-deposited through a shadow mask on the polyimide 08 layer at <1×10⁻⁶ Torr.

The capacitor thus obtained is characterized in the way described in example 1 b above. Results are compiled in table 3.

TABLE 3
Characterization of capacitor containing polyimide 08 layer

| | ρ | εr | εr | εr″ | εr″ | Ed |
|---|---|---|---|---|---|---|
| Polymer | [Ωcm] | 20 Hz | 100 kHz | 20 Hz | 100 kHz | [V/mm] |
| Polyimide 08 | 3.03E+15 | 3.20 | 3.11 | 2.83E−02 | 1.35E−02 | >182 |

### c) Preparation of a Top-Gate, Bottom Contact (TGBC) Field Effect Transistor Comprising a Gate Dielectric Layer of Polyimide 08

Gold is sputtered onto poly(ethylene terephthalate) (PET) foil to form an approximately 40 nm thick film and then source/drain electrodes (channel length: 10 μm; channel width: 10 mm) are structured by photolithography process. A 0.75% (weight/weight) solution of the diketopyrrolopyrrole (DPP)-thiophene-polymer 21-1 (see above) in toluene is filtered through a 0.45 μm polytetrafluoroethylene (PTFE) filter and then applied by spin coating (1300 rpm, 10.000 rpm/s, 15 seconds). The wet organic semiconducting polymer layer is dried at 100° C. on a hot plate for 30 seconds. A 15% (weight/weight) solution of polyimide 08 in 2-Methoxy propylacetate is filtered through a 0.45 μm filter and then applied by spin coating (6000 rpm, 60 seconds). The wet polyimide film is pre-baked at 100° C. for 2 minutes on a hot plate for 2 minutes to obtain a 580 nm thick layer. Gate electrodes of gold (thickness approximately 120 nm) are evaporated through a shadow mask on the polyimide 08 layer. The whole process is performed without a protective atmosphere.

Measurement of the characteristics of the top gate, bottom contact (TGBC) field effect transistors are measured with a Keithley 2612A semiconductor parameter analyser. Drain current I_{ds} in relation to the gate voltage V_{gs} (transfer curve) for the top-gate, bottom-contact (TGBC) field effect transistor comprising a polyimide 08 gate dielectric at a source voltage V_{sd} of −1V (squares), respectively, −20V (triangles) is shown in FIG. 5.

The top-gate, bottom-contact (TGBC) field effect transistor comprising a polyimide 08 shows a mobility of 0.25 cm²/Vs (calculated for the saturation regime) and an Ion/Ioff ration of 8.9 E+4.

The drain current I_{ds} in relation to the drain voltage V_{ds} (output curve) for the top-gate, bottom-contact (TGBC) field effect transistor comprising polyimide 08 at a gate voltage V_{gs} of 0V (stars), −5V (squares), −10V (lozenges), −15V (triangles) and −20V (circles) is shown in FIG. 6.

### Example 4

### Synthesis of Polyimide 33

Polyimide 33 is obtained in analogy to example 2 but using 16.0 mmol of 4,4′-methylene-bis(2,6-diisopropylaniline) dihydrochloride (instead of 10.0 mmol) and 4.0 mmol of 4,4′-methylene-bis(2,6-diethylaniline) instead of 10.00 mmol of 4,4′-methylene-bis(2,6-diethylaniline). The polymer, based on the diamine moieties

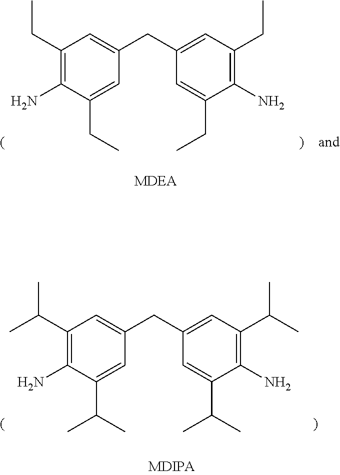 [SMILES: CCc1cc(Cc2cc(CC)c(N)c(CC)c2)cc(CC)c1N ; CC(C)c1cc(Cc2cc(C(C)C)c(N)c(C(C)C)c2)cc(C(C)C)c1N]

in the molar ratio 20:80

### has a Tg of 254° C.

### Comparative Example 1

### Polyimide C1

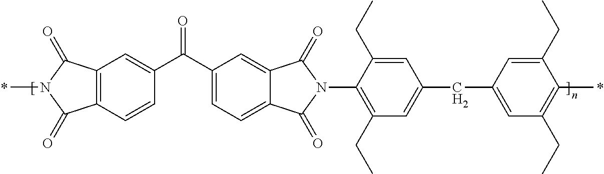

is obtained in analogy to example 1 but replacing 4,4′-methylene-bis(2,6-diisopropylaniline) dihydrochloride by 4,4′-methylene-bis(2,6-diethylaniline). Tg=280° C.

### Comparative Example 2

### Polyimide C2

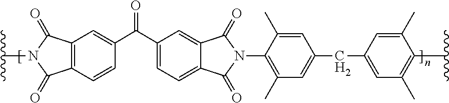

is obtained in analogy to example 1 but replacing 4,4′-methylene-bis(2,6-diisopropylaniline) dihydrochloride by 4,4′-methylene-bis(2,6-dimethylaniline).

### Comparative Example 3

### Solubility

Solubility in the mixture of ethyl lactate and butyl acetate, which is chosen due to its good compatibility with the device production steps, is summarized in the following table:

| Polymer of | soluble |
|---|---|
| Example 1 (invention) | yes |
| Example 2 (invention) | yes |
| Example 4 (invention) | yes |
| C1 (comparison) | no |

### BRIEF DESCRIPTION OF FIGURES

FIG. 1: The drain current I_{ds} in relation to the gate voltage V_{gs} (transfer curve) for the top-gate, bottom-contact (TGBC) field effect transistor of Example 1 (source voltage V_{sd} of −1V (squares); −20V (triangles)).

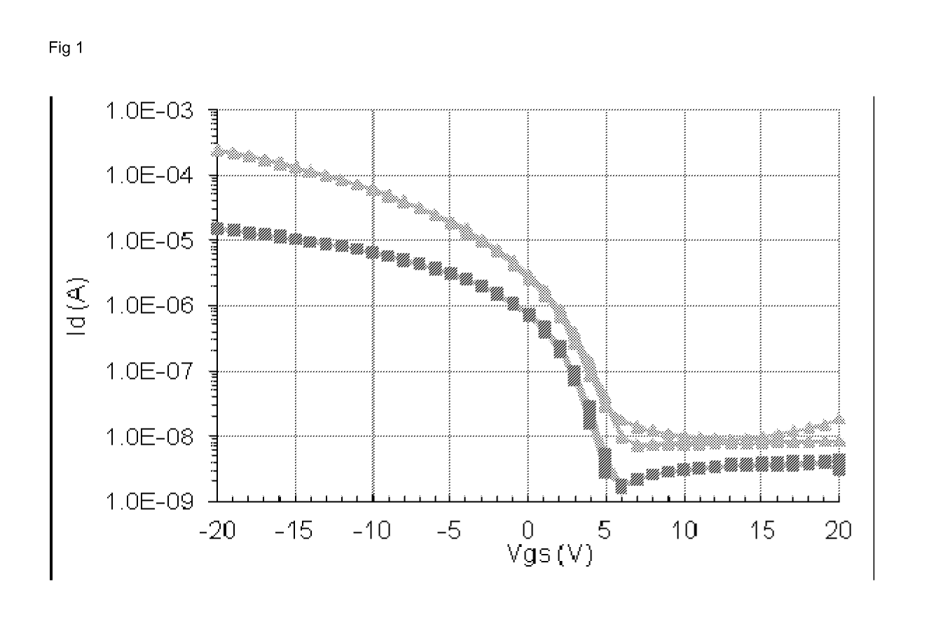

FIG. 2: The drain current I_{ds} in relation to the drain voltage V_{ds} (output curve) for the top-gate, bottom-contact (TGBC) field effect transistor of Example 1 (gate voltage V_{gs} 0V (stars), −5V (squares), −10V (lozenges), −15V (triangles), −20V (circles)).

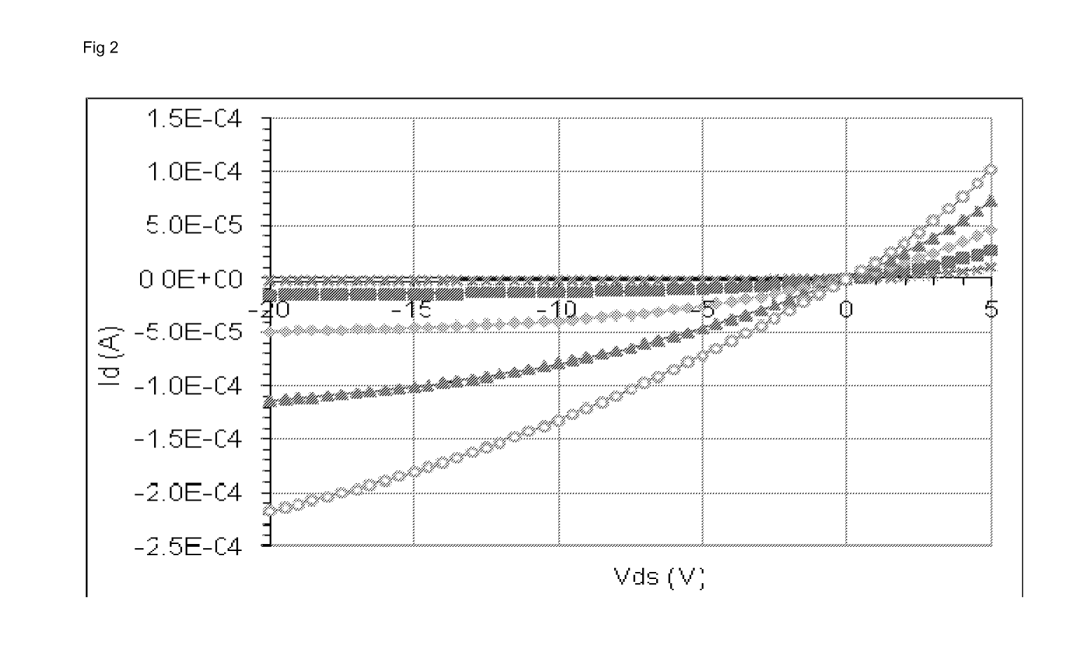

FIG. 3: The drain current I_{ds} in relation to the gate voltage V_{gs} (transfer curve) for the top-gate, bottom-contact (TGBC) field effect transistor of Example 2 (source voltage V_{sd} of −1V (squares), respectively, −20V (triangles)).

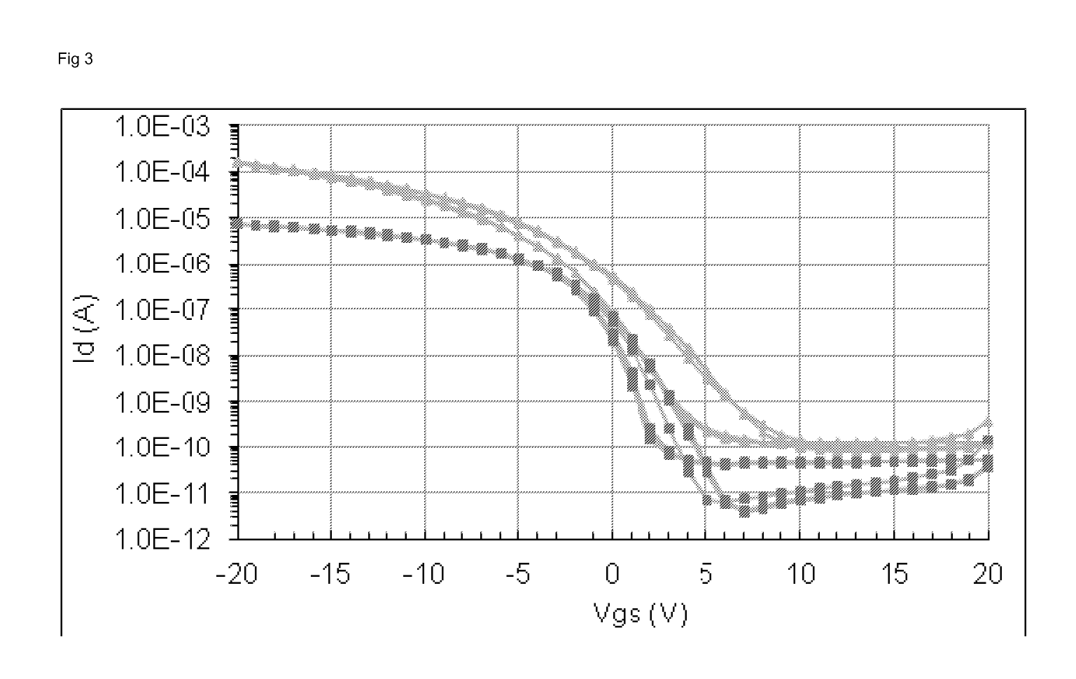

FIG. 4: The drain current I_{ds} in relation to the drain voltage V_{ds} (output curve) for the top-gate, bottom-contact (TGBC) field effect transistor of Example 2 (gate voltage V_{gs} of 0V (stars), −5V (squares), −10V (lozenges), −15V (triangles) and −20V (circles)).

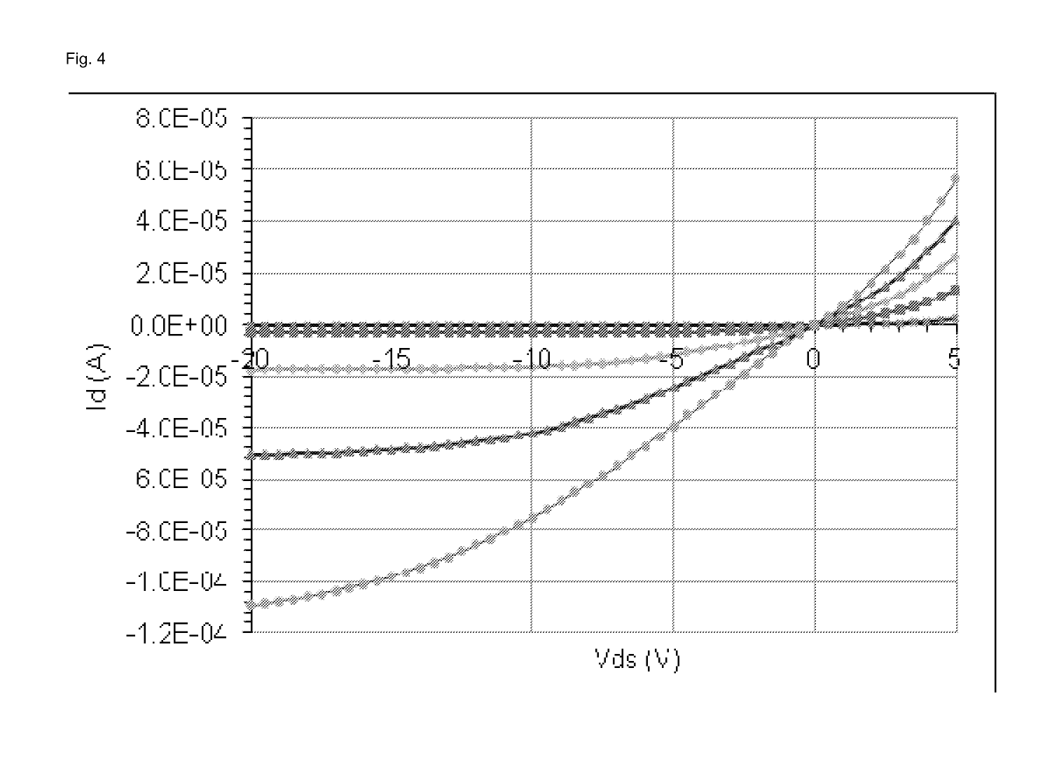

FIG. 5: The drain current I_{ds} in relation to the gate voltage V_{gs} (transfer curve) for the top-gate, bottom-contact (TGBC) field effect transistor of Example 3 (source voltage V_{sd} of −1V (squares), respectively, −20V (triangles)).

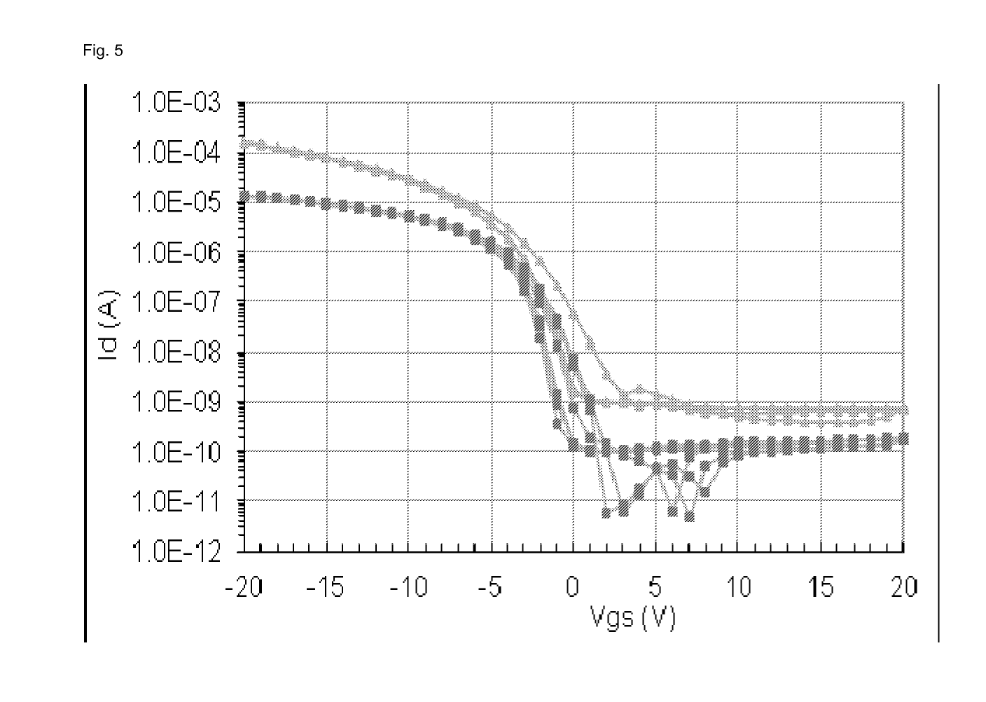

FIG. 6: The drain current I_{ds} in relation to the drain voltage V_{ds} (output curve) for the top-gate, bottom-contact (TGBC) field effect transistor of Example 3 (gate voltage V_{gs} of 0V (stars), −5V (squares), −10V (lozenges), −15V (triangles) and −20V (circles)).

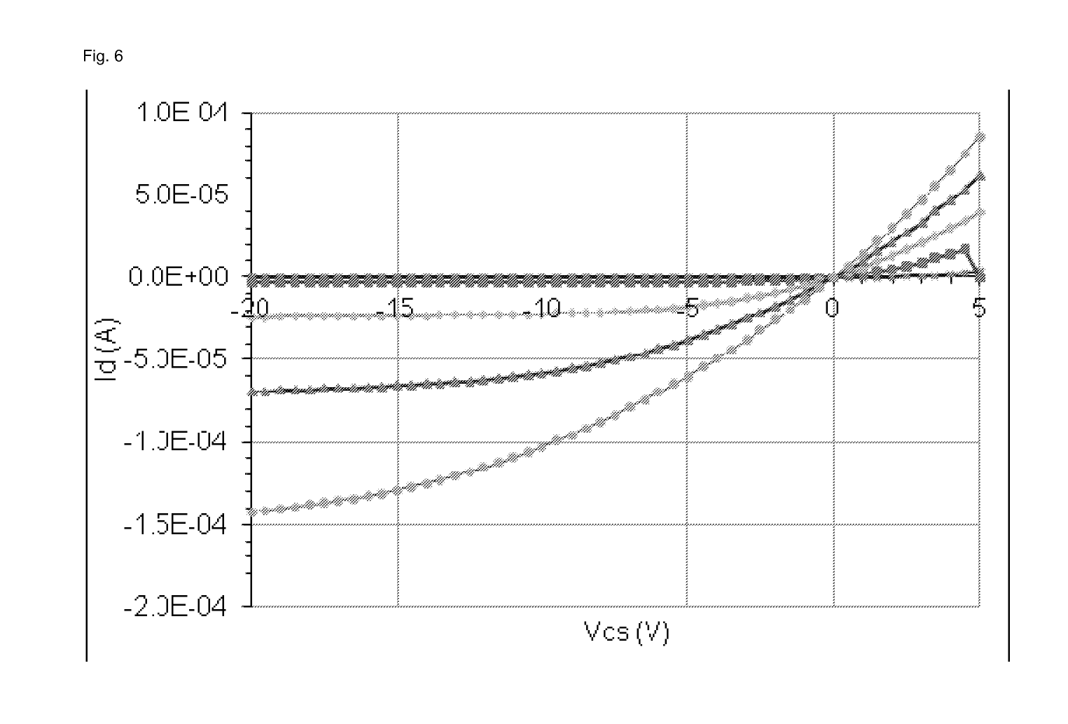

FIG. 7 shows a typical OFET preparation process for Bottom-Gate Bottom-Contact.

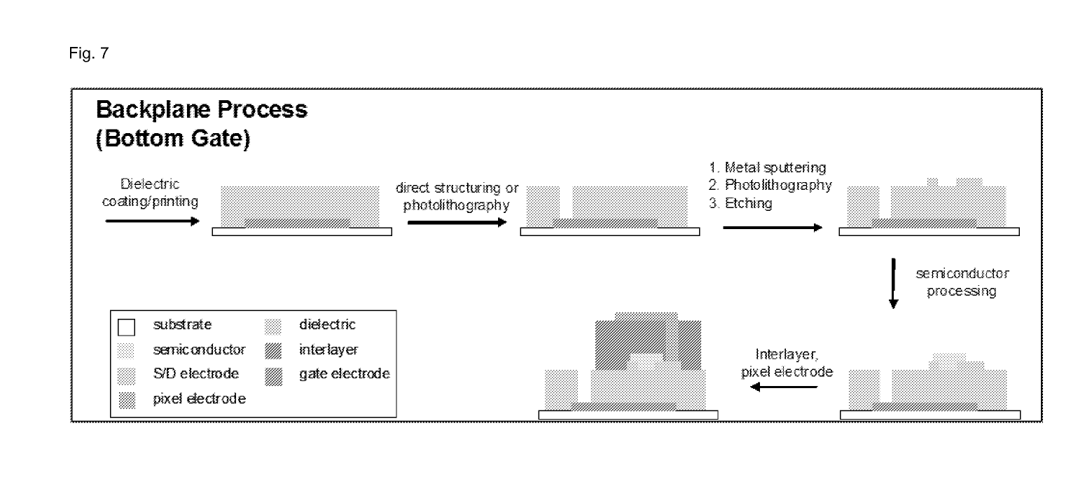

FIG. 8 shows a typical OFET preparation process for Top-Gate Bottom-Contact (TGBC); stages critical with regard to solubility issues highlighted by circles.

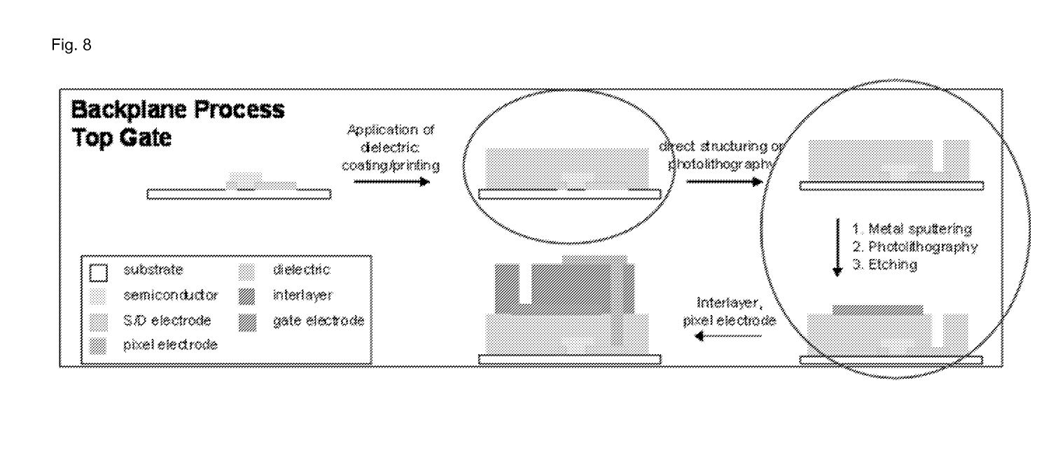

1. An electronic device comprising a dielectric material which comprises a polyimide derived from a primary aromatic diamine and aromatic dianhydride monomer moieties, wherein a moiety comprises a substituent on the aromatic ring selected from the group consisting of propyl and butyl and wherein the primary aromatic diamine has formula 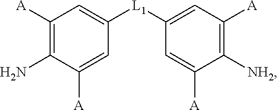
wherein L₁ independently is O, S, C₁₋₁₀alkylene, phenylene or C(O); and each A is independently selected from the group consisting of H and C₁₋₄alkyl, provided that at least 1 of 40 residues A are propyl or butyl.

2. The electronic device of claim 1, which is selected from the group consisting of a capacitor, a transistor, and a device comprising the capacitor, transistor, or both.

3. The electronic device of claim 1, wherein the polyimide conforms to a structure 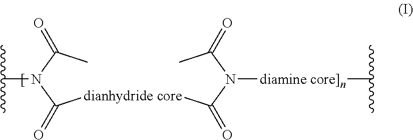
wherein n is from 10 to 100.

4. The electronic device according to claim 1, wherein the primary aromatic diamine is of formula 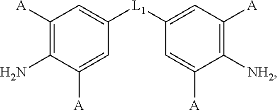
wherein
L₁ independently is C₁-C₃alkylene;
and
each A independently is selected from the group consisting of hydrogen and C₁-C₄alkyl, provided that at least 2 to 39 of 40 residues A in the polyimide A are propyl or butyl.

5. The electronic device according to claim 1, wherein the polyimide comprises moieties of formula (IIa) 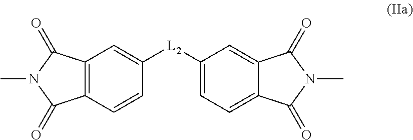
and (IIb) 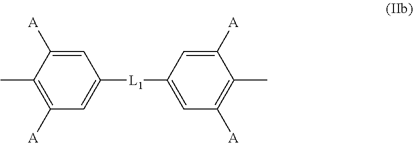
wherein
L₁ independently is O, S, C₁₋₁₀-alkylene, phenylene or C(O);
L₂ independently is selected from the group consisting of carbonyl, oxygen, and sulphur; and
each A independently is selected from the group consisting of hydrogen and C1-C4alkyl, provided that at least 1 of 40 residues A in the polyimide A are propyl or butyl.

6. The electronic device according to claim 1, wherein the polyimide has a glass transition temperature above 150° C., a molecular weight, as determined by gel permeation chromatography, of from 5000 to 1,000,000 g/mol, or both.

7. The electronic device according to claim 1, further comprising a substrate and comprising a further layer of a functional material in direct contact with the polyimide dielectric.

8. The electronic device according to claim 7, wherein the layer of the dielectric material is in direct contact with an electrode layer, a semiconductor layer, or both.

9. The electronic device according to claim 8, wherein the layer of the dielectric material is in direct contact with a semiconductor layer of p-type conductivity.

10. A process of preparation of an electronic device, comprising:
forming a layer comprising polyimide A by applying polyimide A on a layer of a conductor or semiconductor, or on the substrate; and
irradiating and/or heating the layer comprising polyimide A to form a cured layer,
wherein the polyimide A comprises moieties derived from a primary aromatic diamine with an aromatic dianhydride, where the diamine and/or dianhydride moieties are substituted on the aromatic ring by at least one alkyl moiety selected from the group consisting of propyl and butyl.

11. The process according to claim 10, wherein the polyimide is derived from a primary aromatic diamine and aromatic dianhydride monomer moieties, wherein a moiety comprises a substituent on the aromatic ring selected from the group consisting of propyl and butyl, and wherein the primary aromatic diamine has formula 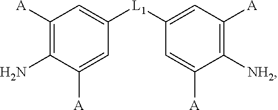
wherein L₁ independently is O, S, C₁₋₁₀alkylene, phenylene or C(O); and each A is independently selected from the group consisting of H and C₁₋₄alkyl, provided that at least 1 of 40 residues A are propyl or butyl.

12. The process according to claim 10, wherein the polyimide A is applied in the forming as a solution in an organic solvent.

13. A polyimide derived from primary aromatic diamine and aromatic dianhydride monomer moieties, wherein the moiety comprises a substituent on the aromatic ring selected from the group consisting of propyl and butyl, wherein the polyimide conforms to structure 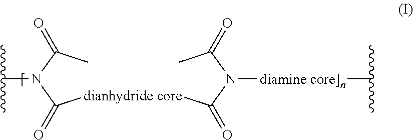
wherein n is from 10 to 100,
and wherein the diamine core is of formula 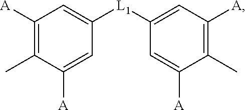
wherein
L₁ independently is O, S, C₁₋₁₀-alkylene, phenylene or C(O);
L₂ independently is selected from the group consisting of carbonyl, oxygen, and sulphur; and
each A independently is selected from the group consisting of hydrogen and C₁-C₄alkyl, provided that at least 1 of 40 residues A in the polyimide A are propyl or butyl.

14. The polyimide of claim 13, wherein the dianhydride core is of formula (IIa) 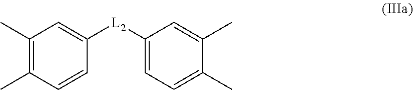
wherein
L₂ independently is selected from the group consisting of carbonyl, oxygen, and sulphur.

15. A method comprising applying the polyimide of claim 13 as a dielectric to a printed electronic device.

16. The electronic device of claim 1, wherein the moiety comprises a substituent on the aromatic ring selected from the group consisting of isopropyl, isobutyl, and tert-butyl.

17. The electronic device of claim 5, wherein L₁ is C_{1-C3}alkylene.

18. The electronic device of claim 8, wherein the layer of the dielectric material is in direct contact with a semiconductor layer of p-type conductivity, comprising a semiconducting material selected from the group consisting of rubrene, tetracene, pentacene, 6,13-bis(triisopropylethynyl)pentacene, diindenoperylene, perylenediimide, tetracyanoquinodimethane, polythiophenes, polyfluorene, polydiacetylene, poly-2,5-thienylenevinylene, poly p-phenylene-vinylene, and polymers comprising repeating units having a diketopyrrolopyrrole group.

19. The process of claim 10, comprising irradiating the layer comprising polyimide A to form a cured layer.

20. The process of claim 10, comprising heating the layer comprising polyimide A to form a cured layer.
